(19) United States
(12) Patent Application Publication
(10) Pub. No.: US 2026/0063989 A1
(43) Pub. Date: Mar. 5, 2026

(54) MONOMER AND POLYMER COMPOSITIONS FOR REVERSIBLE OVERCOAT WAFER PATTERNING

(71) Applicants: The University of Queensland, Brisbane (AU); Tokyo Electron Limited, Tokyo (JP)

(72) Inventors: Andrew Whittaker, Toowong (AU); Idriss Blakey, Mansfield (AU); Hui Peng, Toowong (AU); Josua Markus, Chapel Hill (AU); Md Daloar Hossain, St. Lucia (AU); Michael Murphy, Niskayuna, NY (US); Jodi Grzeskowiak, Schenectady, NY (US); Charlotte Cutler, Albany, NY (US); David Conklin, Saratoga Springs, NY (US)

(21) Appl. No.: 19/057,616

(22) Filed: Feb. 19, 2025

Related U.S. Application Data
(60) Provisional application No. 63/689,605, filed on Aug. 30, 2024.

(51) Int. Cl. G03F 7/004; B29C 71/02; C08F 112/08; C08F 120/30; C08F 120/36; C08J 7/18

(52) U.S. Cl. CPC G03F 7/004; C08F 112/08; C08F 120/30; C08F 120/36; C08J 7/08; C08J 7/18

(57) ABSTRACT

A composition for patterning substrates includes a monomer. The monomer includes a polymerizable unit, a thermally or photochemically activatable crosslinking structure, and an acid-cleavable de-crosslinking structure. The polymerizable unit includes an olefin.

### CROSS-REFERENCE TO RELATED APPLICATIONS

This application claims the benefit of U.S. Provisional Application No. 63/689,605, filed on Aug. 30, 2024, titled “Monomer and Polymer Compositions for Reversible Overcoat Wafer Patterning,” which application is hereby incorporated herein by reference.

### TECHNICAL FIELD

The present invention relates generally to microfabrication of integrated circuits, and in particular to reversible overcoat compositions.

### BACKGROUND

In material processing methodologies, such as photolithography, creating patterned layers typically involves the application of a thin layer of radiation-sensitive material (such as photoresist) to an upper surface of a substrate. This radiation-sensitive material is transformed into a patterned mask that can be used to etch or transfer a pattern into an underlying layer on a substrate. Forming the patterned mask generally involves exposing the radiation-sensitive material to actinic radiation through a reticle, using (for example) a photolithographic exposure system and associated optics. This exposure creates a latent pattern within the radiation-sensitive material that can then be developed.

“Developing” refers to dissolving and removing a portion of the radiation-sensitive material to yield a relief pattern (or topographic pattern). The portion of material removed can be either the irradiated regions or the non-irradiated regions of the radiation-sensitive material, depending on the material's photoresist tone (positive or negative), the type of developing solvent used, or both. Once developed, the relief pattern can function as a mask layer.

Applying and developing a film used for patterning may include thermal treatment, or “baking.” For example, a newly applied film may receive a post-application bake (PAB) to evaporate solvents, to improve material properties (such as structural rigidity or etch resistance), or both. A post-exposure bake (PEB) may be used to set a given pattern and to limit or prevent unintended removal of material during development. Fabrication tools for coating and developing substrates typically include one or more baking modules.

Some photolithography processes include coating a substrate with a photoresist, then exposing the substrate to a pattern of light to create a relief pattern. (In some such processes, a thin film of bottom anti-reflective coating (BARC) may be applied before the photoresist.) The pattern may then be used as a mask or template for additional processing, such as transferring the pattern into an underlying layer, reducing the pitch of the pattern, combining the pattern with other relief patterns, and the like. These processes may serve as discrete steps in the fabrication of microchips.

### SUMMARY

In an embodiment, a composition for patterning substrates includes a monomer. The monomer includes a polymerizable unit, a thermally or photochemically activatable crosslinking structure, and an acid-cleavable de-crosslinking structure. The polymerizable unit includes an olefin.

In another embodiment, a composition for patterning substrates includes a polymer that is soluble in an organic solvent. The polymer includes an organic backbone, a thermally or photochemically activatable crosslinking structure, and an acid-cleavable de-crosslinking structure.

In still another embodiment, a method of patterning a substrate includes forming a plurality of first mandrels over a substrate; coating an overcoat layer over the plurality of first mandrels, the overcoat layer being coated from a composition including a polymer and an organic solvent, the polymer including an organic backbone, a thermally or photochemically activatable crosslinking structure, and an acid-cleavable de-crosslinking structure; inducing a crosslinking reaction within the overcoat layer that renders the overcoat layer insoluble to a predetermined solvent and forms a crosslinked overcoat layer; exposing the substrate to an actinic radiation to generate a plurality of acid particles within the plurality of first mandrels; diffusing a portion of the plurality of acid particles from the plurality of first mandrels into portions of the crosslinked overcoat layer; inducing a de-crosslinking reaction within the portions of the crosslinked overcoat layer to form de-crosslinked regions, where unmodified regions of the crosslinked overcoat layer form a plurality of second mandrels; and selectively removing the de-crosslinked regions. The plurality of first mandrels and the plurality of second mandrels form a mandrel pattern over the substrate.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1I illustrate cross-sectional views of different stages of a method of patterning a substrate with mandrels, wherein FIG. 1A depicts a plurality of mandrels formed over a substrate, FIGS. 1B and 1C depict trimming of the plurality of mandrels, FIG. 1D depicts a resulting plurality of first mandrels, FIG. 1E depicts coating of an overcoat layer over the plurality of first mandrels, FIG. 1F depicts a crosslinked overcoat layer having been formed by an induced reaction, FIG. 1G depicts exposure of the substrate to an actinic radiation to generate a plurality of acid particles within the plurality of first mandrels, FIG. 1H depicts diffusion of a portion of the plurality of acid particles from the plurality of first mandrels into a portion of the crosslinked overcoat layer and formation of de-crosslinked regions within the overcoat layer, and FIG. 1I depicts the mandrel pattern formed by a development process, according to various embodiments;

FIGS. 2A and 2B illustrate compositions for patterning a substrate that comprise a monomer and a polymer, respectively, as well as other components that may be present in such a composition, according to various embodiments;

FIG. 3 illustrates various bonding schemes for monomers comprising a polymerizable unit, a crosslinking structure, and a de-crosslinking structure, according to various embodiments;

FIG. 4 illustrates several polymerizable molecules comprising olefins that may be co-monomers in embodiment copolymers, and further illustrates positional numbering conventions for styrene derivatives;

FIG. 5 illustrates derivatives of hydrocarbacrylate, ethane, and styrene comprising open valences, the derivatives being part of various embodiment monomers and polymers;

FIGS. 6A and 6B illustrate a mechanism for crosslinking chemistry based on thermal loss of a diazo group from an organic molecule, wherein FIG. 6A depicts the mechanism generally and FIG. 6B depicts α-phenyl diazo ester functionality, according to embodiments;

FIG. 7 illustrates a mechanism for crosslinking chemistry based on photochemical formation of a diradical in benzophenone, according to embodiments;

FIGS. 8A-8C illustrate several mechanisms for de-crosslinking chemistry based on acid-catalyzed cleavage of a de-crosslinking structure, wherein FIG. 8A depicts cleavage of an ester to a carboxylic acid and an alcohol by substitution, FIG. 8B depicts cleavage of a tert-butyl ester to a carboxylic acid and isobutylene by elimination; and FIG. 8C depicts cleavage of acetals and hemiacetals, according to various embodiments;

FIGS. 9A and 9B illustrate a crosslinking and de-crosslinking process of a polymerized molecule, wherein FIG. 9A depicts the process schematically and FIG. 9B depicts the process for polymerized 4-(2-diazo-2-phenylacetoxy)-2-methylbutan-2-yl methacrylate (tBuDAz), according to an embodiment;

FIGS. 10A and 10B illustrate structures for compositions comprising a methacrylate unit and an acid-cleavable tertiary-carbon ester with either an α-phenyl diazo ester or a benzophenone, according to embodiments, wherein FIG. 10A depicts monomers and FIG. 10B depicts corresponding polymers;

FIG. 11 illustrates structures for polymer compositions comprising a styrenic unit, an α-phenyl diazo ester, and an acid-cleavable tertiary-carbon ester, according to embodiments;

FIGS. 12A and 12B illustrates copolymer structures that may be part of polymer compositions, according to various embodiments, wherein FIG. 12A depicts copolymer structures comprising n-butyl methacrylate copolymerized with embodiment monomers depicted in FIG. 10A, and FIG. 12B depicts several other polymerized co-monomers that may be present in a copolymer;

FIG. 13 illustrates several base quenchers that may be part of a composition, according to embodiments;

FIG. 14 illustrates several organic solvents that may be part of a composition, according to embodiments; and

FIG. 15 is a flow chart for a method of patterning a substrate, according to various embodiments.

### DETAILED DESCRIPTION OF ILLUSTRATIVE EMBODIMENTS

Continued scaling of semiconductor process nodes is often connected to improvements in the resolution achievable by patterning processes. For example, one approach to improving pattern resolution is spacer technology, which defines a sub-resolution line feature via atomic layer deposition (ALD). A challenge arises, however, when there is a need to create features with opposite tone from the deposited material. In such cases, spacer techniques can involve a complex and costly succession of steps, including over-coating with another material (an “overcoat”) using the spacer features as mandrels; chemical-mechanical planarization (CMP) to reveal the spacer features; and reactive ion etching (RIE) to remove the spacer material, leaving a narrow trench.

Anti-spacer technology is an alternate, self-aligned approach that uses the diffusion length of a reactive species across the boundary between the overcoat and an adjacent layer to define a critical dimension (CD), creating a narrow trench around the features of that adjacent layer after development of the overcoat. When generation of the reactive species is controlled spatially via exposure through a mask, finer features can be formed, such as a narrow slot contact. The CD itself can be tuned based on the physical and chemical properties of the reactive species (e.g., its molecular weight and affinity for interactions with the host material) and by modifying processing conditions such as the bake temperature and bake time in a post exposure bake (PEB). As a result, anti-spacer techniques enable patterning narrow slot-contact features at dimensions beyond the reach of advanced lithographic capabilities.

Anti-spacer formation is a means to achieve self-aligned double patterning (SADP) through spin-on processes, thereby improving throughput and overall cost. Additionally, limitations of conventional SADP processes, such as resolving a single CD across an entire substrate, can be overcome with anti-spacer processes. Because features are formed by the physical generation and subsequent diffusion of a solubility-changing agent across an interface, the formation and mobility of the diffusing species can be modulated across the substrate to enable multiple feature widths in a single process.

To achieve a 1:1 line-space (L/S) mandrel pattern (e.g., equal pitch between mandrels), the initial lithographic exposure may be biased to account for the addition of a mandrel or anti-spacer and to achieve the target pitch. The density of the final pattern, however, is limited within anti-spacer flows exhibiting change in CD of a single mandrel, as is particularly apparent when the final target pitch approaches one-half the resolution limit of the lithographic exposure.

In this limit, the correct bias is no longer resolvable, and additional post-exposure processes must be employed. Resolution limitations may prevent biasing the incoming L/S pattern to enable symmetrical L/S patterning and result in asymmetrical L/S patterning after multi-patterning processing. In particular, some features may remain limited by the resolution of the lithography process.

Embodiments described in this disclosure provide monomer and polymer compositions comprising crosslinking and de-crosslinking structures. In various embodiments, these compositions enable patterning a semiconductor substrate, for example, patterning a substrate with a reversible overcoat (ROC) layer for anti-spacer patterning schemes achieving sub-lithographic critical dimension. In embodiment schemes, diffusion of a solubility-changing agent outward from the photoresist mandrels into the reversible overcoat may promote a de-crosslinking reaction that forms narrow trenches on development. The resulting process flow overcomes the pitch limitations of an acid-in unidirectional diffusion process flow to achieve a symmetrical sub-lithographic mandrel pattern. Moreover, because a single composition may both crosslink and de-crosslink, embodiments advantageously enable formation of both trenches and lines from a corresponding material.

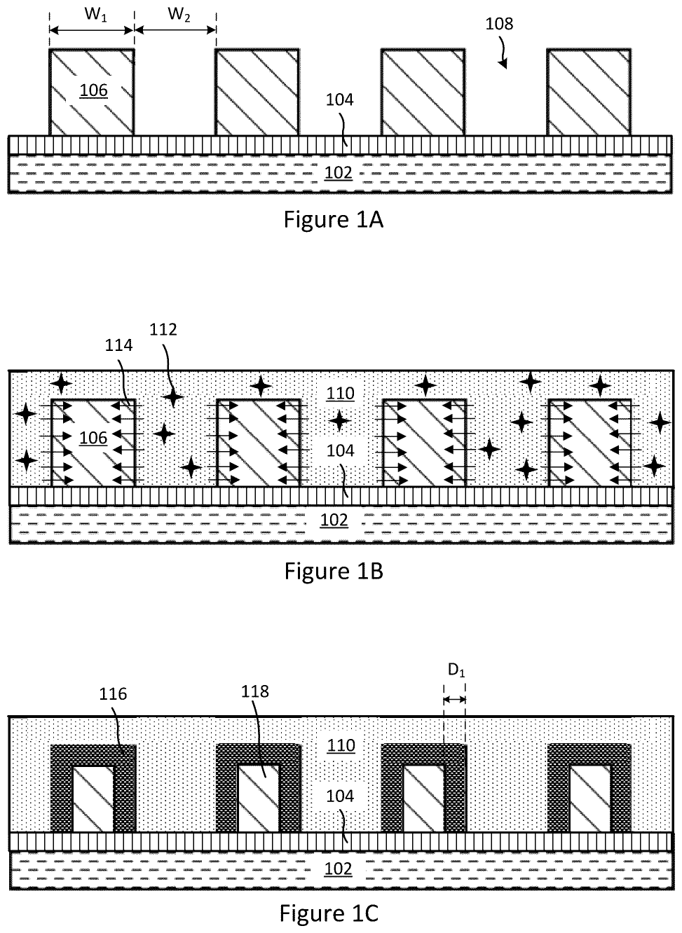

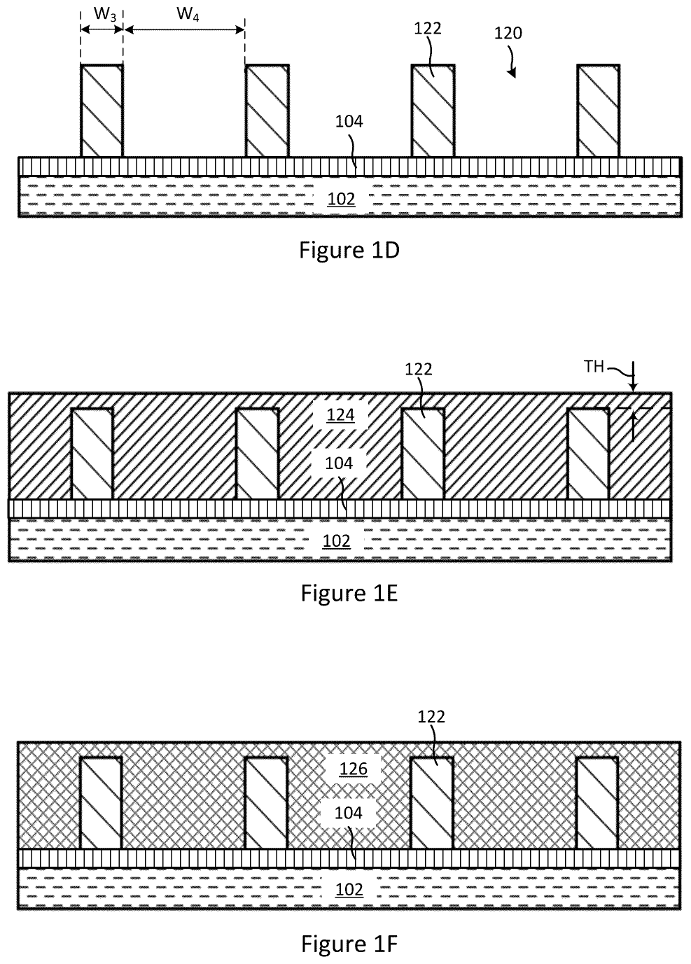

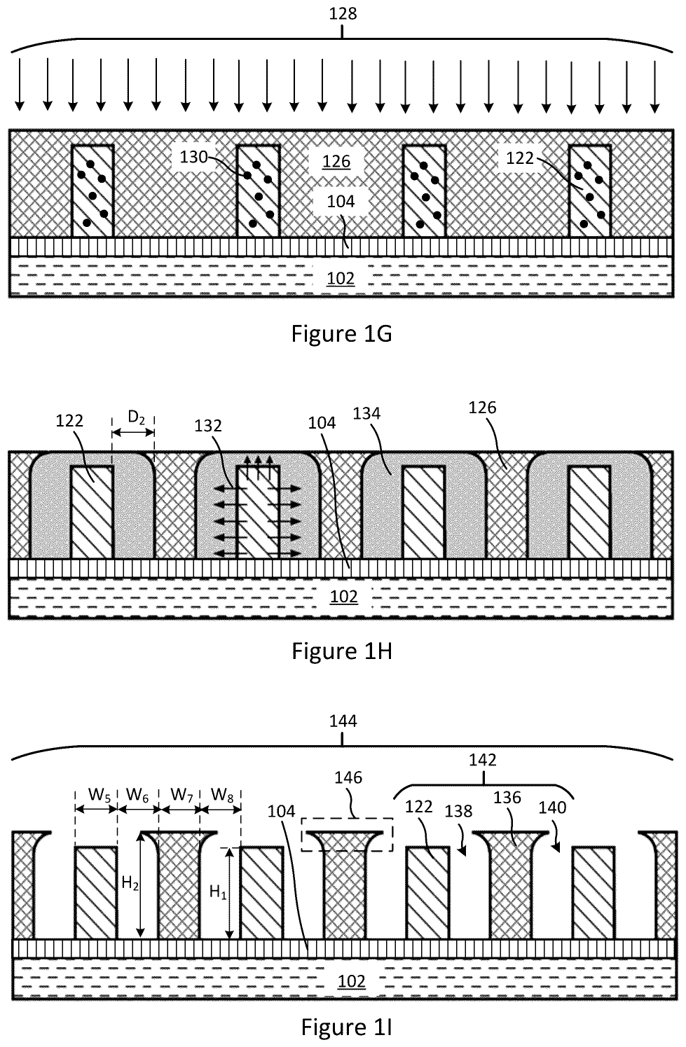

In the detailed description that follows, embodiments are described first with reference to a process flow for patterning a substrate according to an anti-spacer patterning scheme incorporating the use of a reversible overcoat, as illustrated in FIGS. 1A-1I.

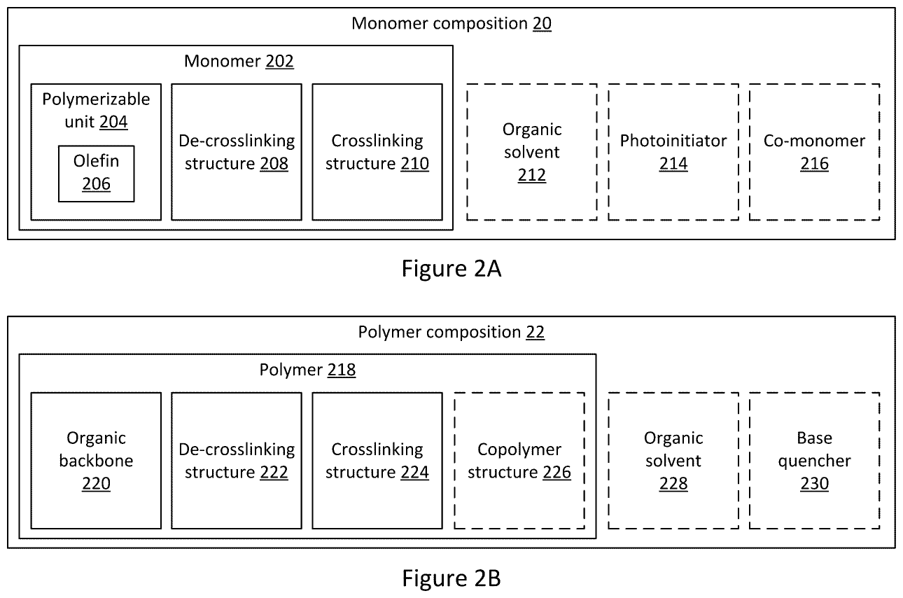

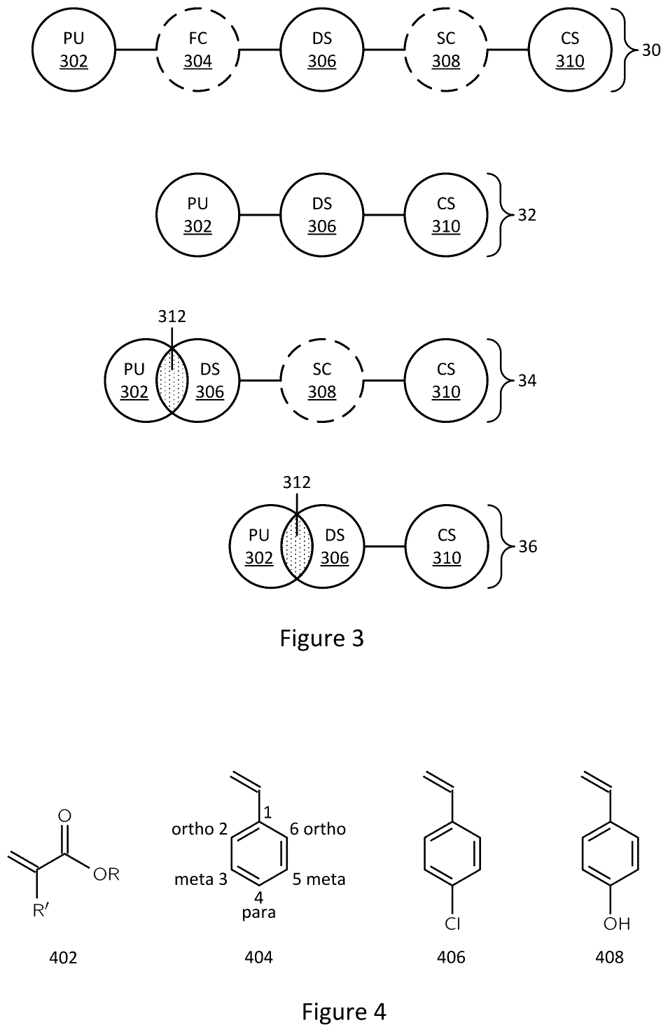

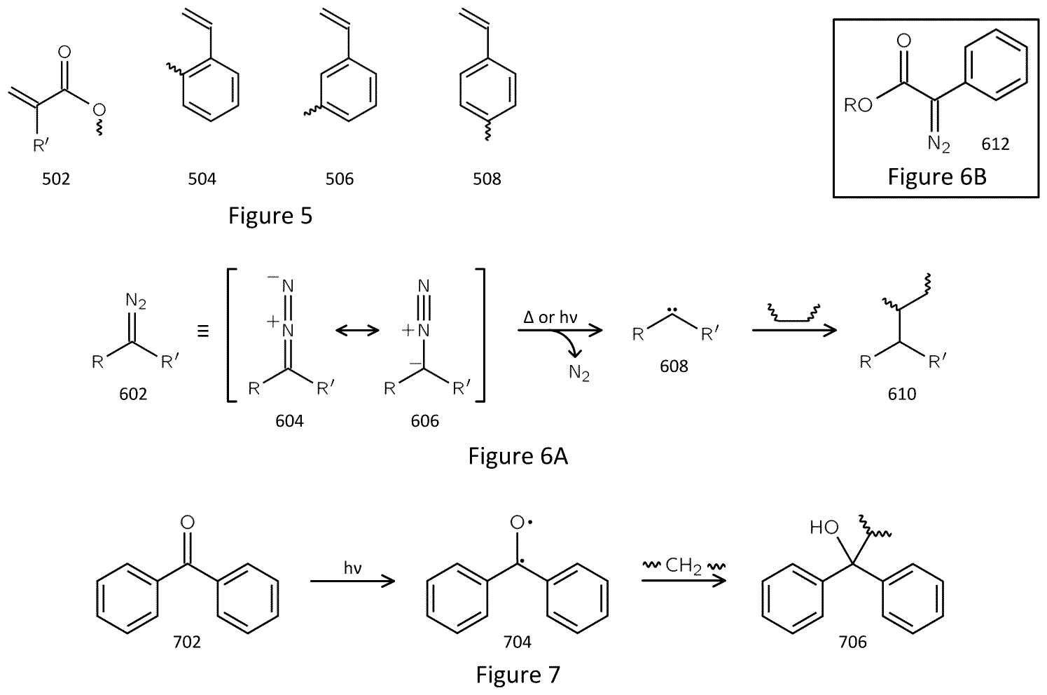

ROC compositions comprising a monomer or a polymer, respectively, are then described with reference to FIGS. 2A and 2B. Embodiment compositions may comprise a polymerizable unit, a crosslinking structure, and a de-crosslinking structure, among other components; as such, various structural schemes are described with reference to FIG. 3. A selection of polymerizable molecules and corresponding polymerizable units are described with reference to FIGS. 4 and 5.

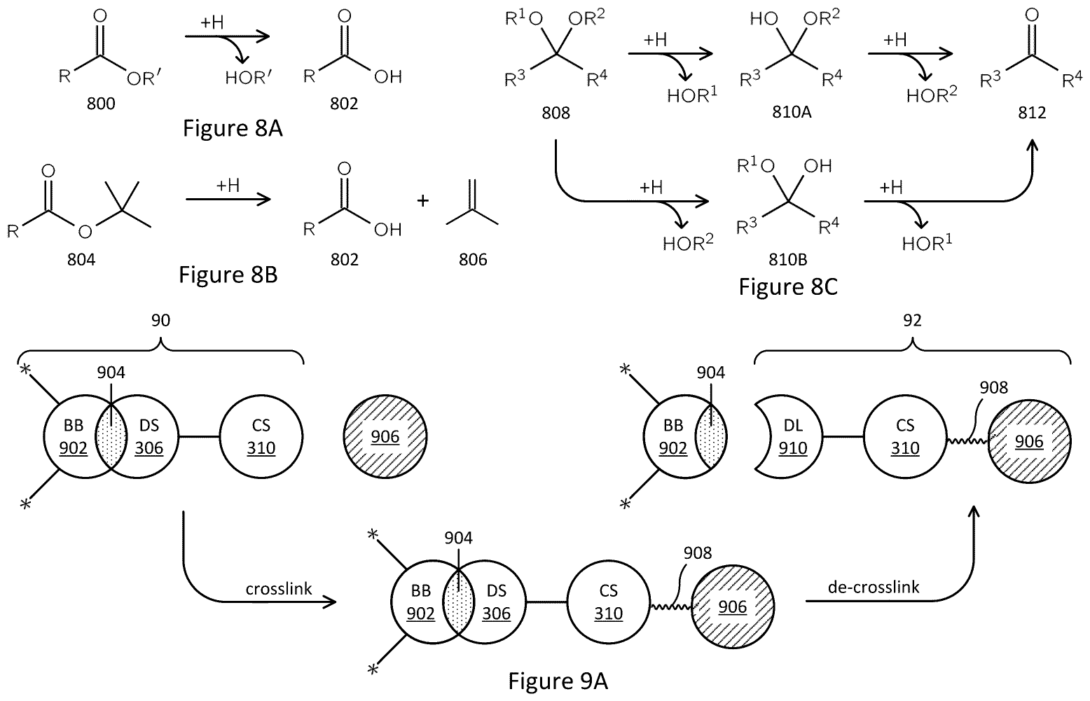

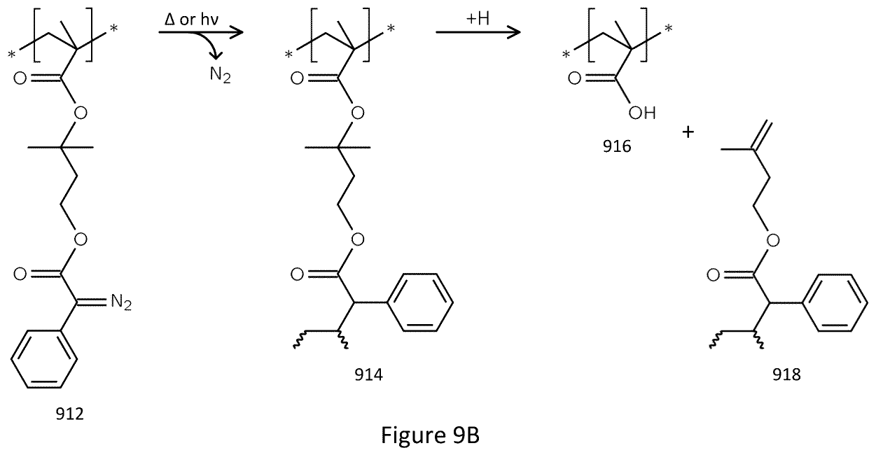

Chemistry for crosslinking and de-crosslinking is described next, with reference to FIGS. 6A/6B, FIG. 7, and FIG. 8. A schematic illustration of stepwise crosslinking and de-crosslinking of a polymer side chain in FIG. 9A complements a specific example of crosslinking and de-crosslinking for an embodiment comprising polymerized 4-(2-diazo-2-phenylacetoxy)-2-methylbutan-2-yl methacrylate (tBuDAz), as depicted in FIG. 9B. Embodiments comprising tBuDAz, as well as other embodiments described herein, advantageously enable crosslinking and de-crosslinking by orthogonal mechanisms and without entailing the inclusion of a separate molecular crosslinker.

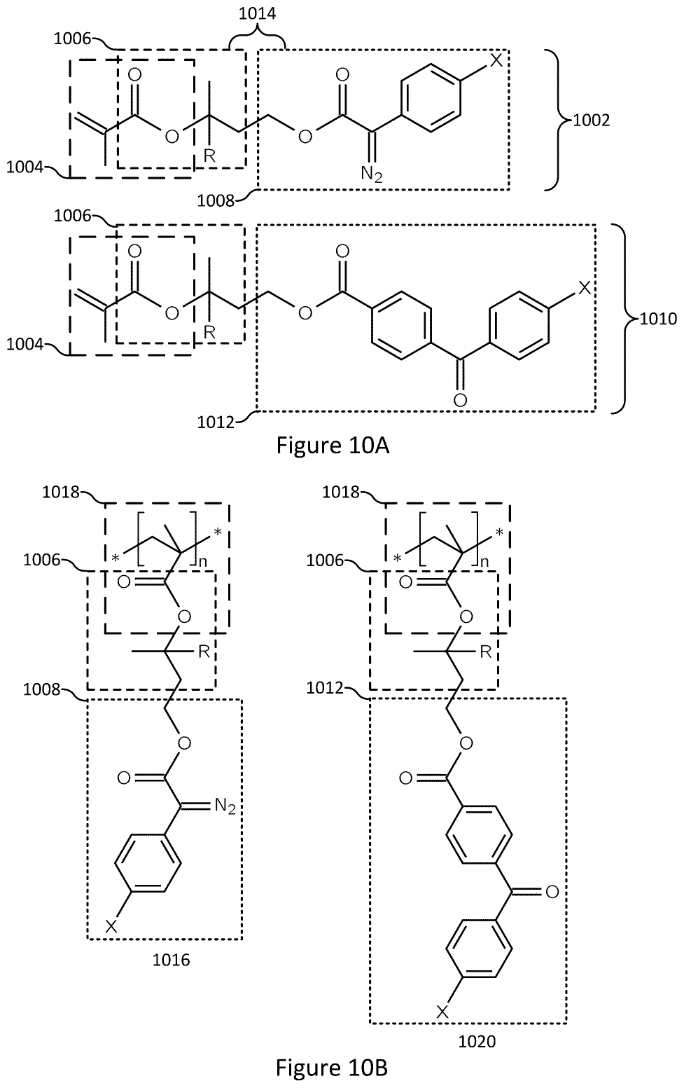

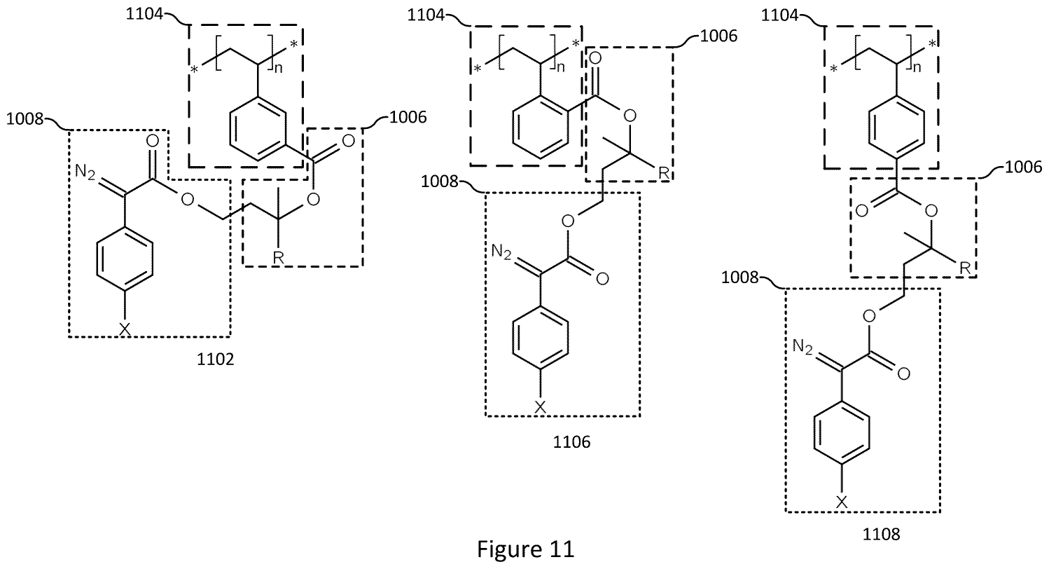

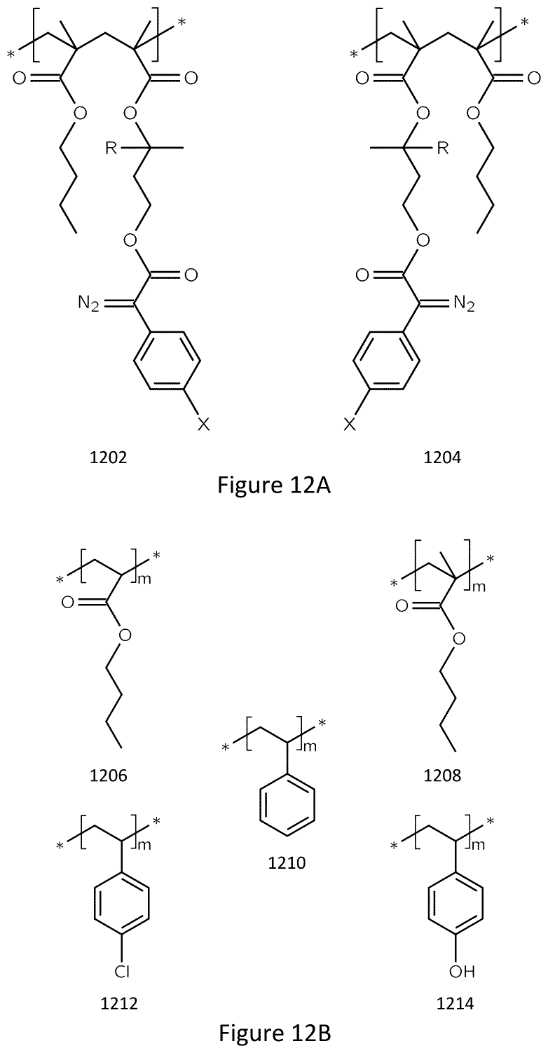

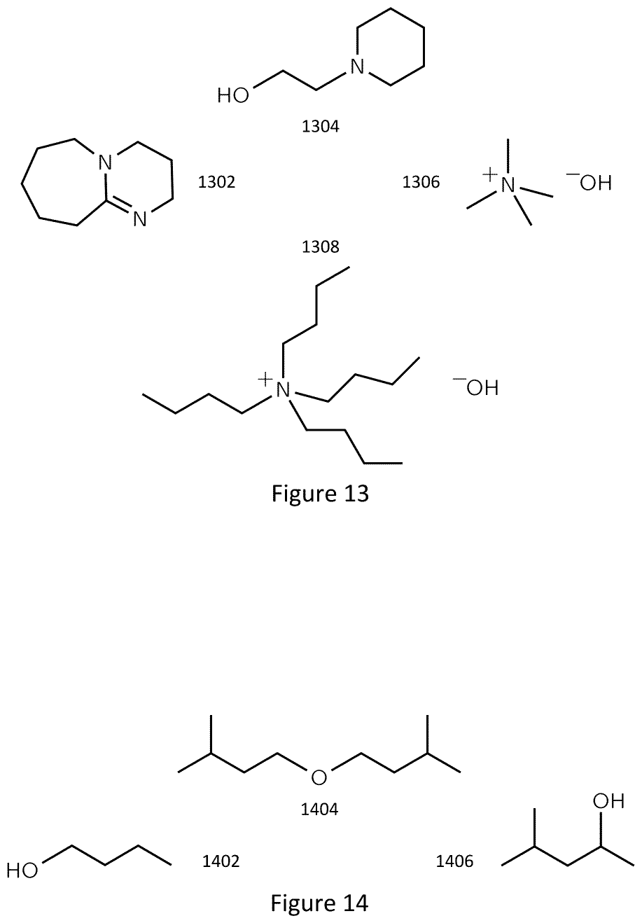

Embodiment monomers and polymers—some similar to tBuDAz but comprising variable backbone structure, crosslinking functionality, additional substituents, or combinations thereof—are described with reference to FIGS. 10A/10B and FIG. 11. Structural motifs that may be present in various embodiment copolymers are then described with reference to FIGS. 12A/12B. Other possible components of embodiment compositions, such as base quenchers and solvents, are described next, with reference to FIGS. 13 and 14.

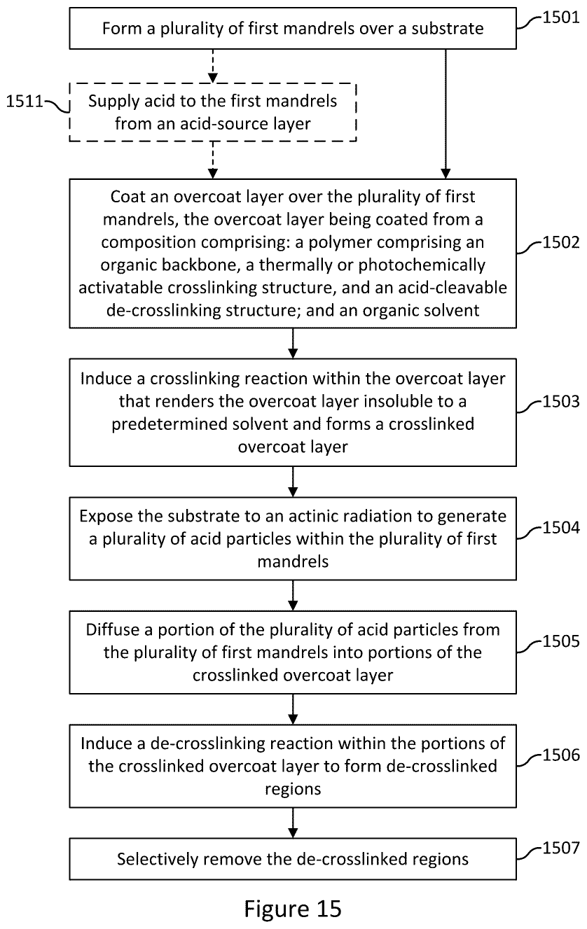

To conclude the detailed description, a more general method of patterning a substrate is described with reference to a flow chart presented in FIG. 15.

FIGS. 1A-1I illustrate cross-sectional views of different stages of a method of patterning a substrate with mandrels. Referring to FIG. 1A, a plurality of mandrels 106 is formed over a substrate 102. The substrate 102 may be a part of, or include, a semiconductor device or a semiconductor structure, and may be formed in any suitable manner, such as by any suitable combination of deposition, lithography, and etch techniques. For example, the semiconductor structure may comprise the substrate 102, in which various device regions are formed. In certain embodiments, the substrate 102 may comprise isolation regions (such as shallow-trench isolation regions), diffusion regions, and other regions formed therein.

The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or another compound semiconductor. In other embodiments, the substrate 102 may comprise heterogeneous layers such as silicon germanium on silicon, gallium nitride on silicon, silicon carbon on silicon, or layers of silicon on a silicon or SOI substrate. In various embodiments, the substrate 102 may be patterned or embedded in other components of the semiconductor device or the semiconductor structure.

Referring further to FIG. 1A, in some embodiments, an intermediate layer 104 is formed over the substrate 102, such that the mandrels 106 are formed over the intermediate layer 104. The intermediate layer 104 may be a target for pattern transfer in subsequent processing after formation of the mandrel pattern 144 (see FIG. 11) is completed.

The intermediate layer 104 may comprise silicon, silicon oxynitride, organic material, non-organic material, amorphous carbon, or the like. The intermediate layer 104 may be selected to have anti-reflective properties, such as by incorporating a silicon bottom anti-reflective coating (Si-BARC), for example.

The intermediate layer 104 may be a mask layer comprising a hard mask, in some embodiments. Further, the intermediate layer 104 may be a stacked hard mask comprising, for example, two or more layers of two or more different materials. In embodiments comprising a bilayer hard mask, a first layer of the bilayer may comprise a metal-based layer such as titanium nitride, titanium, tantalum nitride, tantalum, tungsten-based compounds, ruthenium-based compounds, or aluminum-based compounds, and a second layer of the bilayer may comprise a dielectric layer such as silicon dioxide, silicon nitride, silicon oxynitride, silicon carbide, amorphous silicon, or polycrystalline silicon.

The intermediate layer 104 may be deposited using suitable deposition processes. Suitable deposition processes may comprise spin-on coating, chemical vapor deposition (CVD), atomic layer deposition (ALD), plasma deposition processes (e.g., plasma-enhanced CVD (PECVD) or plasma-enhanced ALD (PEALD)), or other layer deposition processes or combinations thereof.

In some embodiments, the mandrels 106 may be formed by disposing a photoresist layer (not illustrated) over the intermediate layer 104 and patterning the photoresist layer using suitable lithographic techniques. The photoresist layer may comprise a positive-tone photoresist or a negative-tone photoresist. In the embodiment illustrated and described herein, the photoresist layer comprises a positive-tone chemically amplified photoresist (CAR).

The photoresist layer may be deposited on the substrate 102 in any suitable manner. For example, the photoresist layer may be deposited by spin coating, spray coating, thermal spray coating, dip coating, flow coating, or roll coating. As a particular example, the photoresist layer may be deposited on the substrate 102 using a spin-on deposition technique (spin coating).

In various embodiments, the photoresist layer may comprise an agent-generating ingredient that, in response to a suitable agent-activation trigger (e.g., heat or radiation), generates a solubility-changing agent (e.g., an acid). Example agent-generating ingredients may include a thermal-acid generator (TAG) that is configured to generate an acid in response to heat (i.e., thermally) or a photoacid generator (PAG) that is configured to generate an acid in response to actinic radiation (i.e., photochemically).

With spin-on deposition, a particular material (e.g., a material of the photoresist layer) is deposited on the substrate 102 (e.g., on the intermediate layer 104 formed on the substrate 102). The substrate 102 is then rotated (if not already rotating, possibly at a relatively low velocity) at a relatively high velocity so that centrifugal force causes the deposited material to move toward edges of the substrate 102, thereby coating the substrate 102. Excess material is typically spun off the substrate 102. In some embodiments, excess material deposited at the edges of the substrate 102 (an edge bead) may be removed from the substrate by a conventional process.

In certain embodiments, spin-on deposition comprises dispensing liquid chemicals onto the substrate 102 (e.g., onto a top surface of the intermediate layer 104) using a coating module with a liquid delivery system that may dispense one or more types of liquid chemicals. The dispense volume may be in a range from 0.2 mL to 10 mL, for example, in a range from 0.5 mL to 2 mL. The substrate 102 may be supported by and secured to a rotating chuck. The rotating speed during the liquid dispense may be in a range from 50 rpm to 3000 rpm, for example, in a range from 1000 rpm to 2000 rpm.

A system used for spin-on deposition may further comprise an anneal module that may bake or deliver light to the substrate 102 after the liquid chemicals have been dispensed. It should be understood that this example spin-on deposition technique and associated values are provided as examples only. In other embodiments, the photoresist layer may be deposited using a CVD process, a PECVD process, an ALD process, a PEALD process, or other suitable processes.

After forming the photoresist layer, a reticle (not illustrated) is disposed over the photoresist layer. The reticle may be used to modulate a dose (or an intensity) of a radiation (e.g., actinic radiation) that is used to expose the photoresist layer. In such embodiments, the reticle may comprise regions with different degrees of transparency to the radiation (e.g., opaque and transparent regions). The photoresist layer is then subject to an exposure step with radiation delivered through the reticle. The radiation forms exposed regions of the photoresist layer, while unexposed (or unmodified) regions of the photoresist layer are protected by the reticle.

The exposure step may be performed using a photolithographic technique such as dry lithography (e.g., 193 nm dry lithography), immersion lithography (e.g., 193 nm immersion lithography), i-line lithography (e.g., using 365 nm UV radiation), h-line lithography (e.g., using 405 nm UV radiation), extreme UV (EUV) lithography (e.g., using 13.5 nm UV radiation), deep UV (DUV) lithography (e.g., using 254 nm, 266 nm, or 284 nm UV radiation), or any other suitable photolithography technology. In some embodiments not comprising a reticle, the exposure step may be performed by electron-beam lithography using electrons with energy between 100 eV and 150 keV.

In some embodiments, the radiation generates an acid in the exposed regions of the photoresist layer. The acid may be generated from a PAG that is present in the photoresist layer under the influence of the radiation. The acid may then react with the material of the photoresist layer and alter the solubility of the exposed regions of the photoresist layer. Subsequently, the exposed regions of the photoresist layer are removed by performing a developing process using a suitable developer. The developing process forms a plurality of openings 108 (see FIG. 1A) in the photoresist layer that expose portions of the intermediate layer 104. The unexposed regions of the photoresist layer form the plurality of mandrels 106.

The mandrels 106 may have a first width W₁ and the openings 108 may have a second width W₂. In some embodiments, the first width W₁, the second width W₂, or both may have the smallest value achievable by the lithographic techniques used. In the illustrated embodiment, a ratio W₁:W₂ equals 1:1.

Referring to FIG. 1B, a trim layer 110 is deposited over the substrate 102 in any suitable manner, such as by any of the various coating methods described above. As a particular example, the trim layer 110 may be deposited on the substrate 102 using spin coating. The trim layer 110 may fill the openings 108 (see FIG. 1A) and cover top surfaces of the mandrels 106.

A material for the trim layer 110 may be chosen such that the trim layer 110 can be removed by a subsequent developing process, as described below in greater detail. In some embodiments, the trim layer 110 may be a multicomponent material that, as deposited, comprises a first component and a second component. The first component may be, for example, a polymer. The second component may be, for example, a solubility-changing agent 112, such as an acid (e.g., a free acid). In the illustrated embodiment, the solubility-changing agent 112 comprises a plurality of acid particles that are depicted as filled 4-pointed stars (see FIG. 1B).

As another example, the second component may be an agent-generating ingredient that generates a solubility-changing agent (e.g., an acid) in response to a suitable agent-activation trigger (e.g., heat or radiation). Example agent-generating ingredients may comprise a TAG that is configured to generate an acid in response to heat or a PAG that is configured to generate an acid in response to actinic radiation.

For example, in embodiments in which the trim layer 110 includes a free acid, a solubility-changing agent 112 may be the free acid, and subsequent baking of the substrate 102 may cause the free acid to diffuse into perimeters of the mandrels 106 (as indicated by arrows 114) and cause corresponding portions of the mandrels 106 to become soluble in a developer.

As another example, in embodiments in which the trim layer 110 includes a TAG as an agent-generating ingredient, subsequent baking of the substrate 102 may cause the TAG to generate a solubility-changing agent 112 (e.g., acid), which may be referred to as activating the acid. The baking may further cause the generated solubility-changing agent 112 to diffuse into perimeters of the mandrels 106 (as indicated by arrows 114) and cause corresponding portions of the mandrels 106 to become soluble in a developer.

As yet another example, in embodiments in which the trim layer 110 includes a PAG as an agent-generating ingredient, an exposure step that includes exposing the trim layer 110 to a radiation (e.g., actinic radiation) may be performed prior to baking the substrate 102. The exposure step may cause the PAG to generate a solubility-changing agent 112 (e.g., acid), which may be referred to as activating the acid. Subsequent baking of the substrate 102 may cause the generated solubility-changing agent 112 to diffuse into perimeters of the mandrels 106 (as indicated by arrows 114) and cause corresponding portions of the mandrels 106 to become soluble in a developer.

Referring to FIG. 1C, a baking process is performed on the substrate 102. In certain embodiments, the baking process may be a thermal process that is performed by heating the substrate 102 in a process chamber, in vacuum or under a gas flow. The baking may be performed at a temperature between 50° C. and 250° C., for example, between 60° C. and 140° C. In a particular example, the substrate 102 is baked for a period between 1 min and 3 min.

Bake conditions may be selected to promote diffusion of the solubility-changing agent 112 (and, if applicable, to promote generation of the solubility-changing agent 112 from an agent-generating ingredient of the trim layer 110 such as a TAG). Bake conditions may thus be used to tune solubility of the perimeters of the mandrels 106 to a target first depth D₁ (see FIG. 1C). The first depth D₁ may be tuned by parameters of the baking process (such as, for example, a bake temperature and a bake duration) as well as material parameters (such as, for example, a polymer composition of the mandrels 106 and an acid composition and an acid concentration in the trim layer 110).

With further reference to FIGS. 1B and 1C, the solubility-changing agent 112 chemically reacts with a material of the mandrels 106 to form modified regions 116 of the mandrels 106. The chemical reaction changes the solubility of the modified regions 116 of the mandrels 106 so that the modified regions 116 of the mandrels 106 can be removed in a subsequent developing process. Each modified region 116 extends along sidewalls and a top surface of an unmodified region 118 of a respective mandrel 106.

Referring to FIG. 1D, a developing process is performed on the substrate 102 using a suitable developer. In various embodiments, the developer may comprise a metal ion-free (MIF) developer, for example, an aqueous solution of tetramethylammonium hydroxide (TMAH). In other embodiments, the developer may comprise a metal ion-containing developer, for example, an aqueous solution of sodium hydroxide (NaOH) or potassium hydroxide (KOH). In some embodiments, the developing process may comprise dipping or soaking the substrate 102 in the developer. In other embodiments, the developing process may comprise rinsing or spraying the substrate 102 with the developer once or repeatedly.

In some embodiments, the developer removes the trim layer 110 (see FIG. 1C) and the modified regions 116 (see FIG. 1C), thus forming openings 120 that expose the intermediate layer 104. The remaining unmodified regions 118 (see FIG. 1C) of the mandrels 106 form a plurality of first mandrels 122 over the intermediate layer 104. The processes described with reference to FIGS. 1B-1D may be collectively referred to as trimming the mandrels 106.

The first mandrels 122 may have a third width W₃, and the openings 120 may have a fourth width W₄. The third width W₃ of the first mandrels 122 is less than the first width W₁ of the mandrels 106 (see FIG. 1A). In some embodiments in which the first width W₁ has the smallest value achievable by the lithography process, the first mandrels 122 have a sub-lithographic width. The fourth width W₄ of the openings 120 is greater than the second width W₂ of the openings 108 (see FIG. 1A). In the illustrated embodiment (see FIG. 1D), a ratio W₃:W₄ equals 1:3. Such a pattern of the first mandrels 122 may be also referred to as a 1:3 line-space (L/S) pattern. In other embodiments, a ratio W₃:W₄ may be in a range from 1:2 to 1:5.

In some embodiments, though not as illustrated, the first mandrels 122 of FIG. 1D may optionally be supplied with acid at this stage, such as in the form of agent-generating ingredients (e.g., a PAG with a relatively high diffusion constant) or solubility-changing agents (e.g., free acid). In particular, an acid-source layer comprising a polymer together with the desired acid source may be formed over the substrate 102 by any of the various coating methods described above (e.g., by spin coating). The acid-source layer may fill the openings 120 (see FIG. 1D) and cover top surfaces of the first mandrels 122. The substrate 102 may be baked to promote diffusion of the PAG or free acid from the acid-source layer into the first mandrels 122, with bake temperature and time selected to yield diffusion of acid to a target depth. The acid-source layer may then be developed and removed using an organic solvent suitable for overcoats, such as methyl isobutyl carbinol. In some embodiments in which the first mandrels 122 comprise a photoresist material not formulated to include acid, the acid-source layer may be used to introduce it.

Referring to FIG. 1E, an overcoat layer 124 may be deposited over the substrate 102 in any suitable manner, such as by any of the various coating methods described above. As a particular example, the overcoat layer 124 may be deposited on the substrate 102 using spin coating. The overcoat layer 124 may fill the openings 120 (see FIG. 1D) and cover top surfaces of the first mandrels 122 such that the overcoat layer 124 has a thickness TH over the top surfaces of the first mandrels 122. The overcoat layer 124 may be also referred to as a reversible overcoat (ROC) layer.

Embodiments of this application disclose compositions for overcoat films such as the overcoat layer 124. These compositions enable the film to be crosslinked and subsequently de-crosslinked—such that they are “reversible overcoats,” or ROCs—through processing steps compatible with advanced pitch-splitting process flows like that described above. In particular, the compositions disclosed herein provide ROCs appropriate for application to a substrate 102 to form the overcoat layer 124 (see FIG. 1E) and subsequently to undergo crosslinking to form the crosslinked overcoat layer 126 (see FIGS. 1F-1H below). Moreover, and according to embodiments, the crosslinking may be a self-crosslinking process, in which the ROC material crosslinks as a consequence of its own chemical structure, even in the absence of separate molecular crosslinkers.

A material of the overcoat layer 124 may be selected not to intermix with a material of the first mandrels 122 and to crosslink at a temperature lower than a glass transition temperature T_{g} of the photoresist material in the first mandrels 122. The material of the overcoat layer 124 may comprise a polymer configured to self-crosslink in response to a thermal or photochemical activating trigger and further configured to de-crosslink in the presence of acid. Embodiment monomer and polymer compositions enabling a self-crosslinking reversible overcoat layer 124 are described in detail below.

Referring to FIG. 1F, and in some embodiments, a baking process may then be performed on the substrate 102 to induce (self-)crosslinking within the overcoat layer 124, thereby making the crosslinked overcoat layer 126 insoluble in a developer to be used subsequently. In certain embodiments, the baking process may be a thermal process that is performed by heating the substrate 102 in a process chamber to a temperature between 50° C. and 300° C., in vacuum or under a gas flow. In an implementation, the baking may be performed at a temperature less than 160° C. for fewer than 6 min. In some embodiments, the baking may be performed a temperature less than 130° C. for fewer than 2 min.

In other embodiments, but not as illustrated, the crosslinking depicted in FIG. 1F may be activated photochemically, such as by exposure to an actinic radiation of any of the types described above with respect to FIG. 1A, without any need for a concurrent or accompanying baking process. In certain embodiments in which the crosslinking functionality of the overcoat layer 124 is configured to be trigged by relatively longer wavelengths, the actinic radiation activating crosslinking might further comprise g-line radiation (436 nm) or other visible light.

For example, in some embodiments the crosslinking may be activated strictly photochemically and at an ambient temperature, such as a room temperature between 20° C. and 25° C. In other embodiments comprising photochemical activation of the crosslinking, the substrate 102 may still be heated in vacuum or under a gas flow in order to facilitate crosslinking, such as by increasing the rate of the crosslinking reaction.

Referring to FIG. 1G, agent-generating ingredients within the first mandrels 122 are then decomposed to generate a solubility-changing agent 130 (e.g., free acid). In the illustrated embodiment, the solubility-changing agent 130 comprises a plurality of acid particles that are depicted as filled circles. In some embodiments in which the agent-generating ingredients comprise a PAG, the solubility-changing agent 130 (e.g., free acid) is generated in response to exposing the first mandrels 122 to a radiation 128 (e.g., actinic radiation of the types described above with reference to FIG. 1A). In some embodiments, the substrate 102 is flood exposed to the radiation 128. In such embodiments, each of the first mandrels 122 may comprise a substantively similar amount of the solubility-changing agent 130 (e.g., free acid).

Referring to FIG. 1H, a baking process is performed on the substrate 102. The baking process diffuses the solubility-changing agent 130 out of the first mandrels 122 (as indicated by arrows 132) and into the crosslinked overcoat layer 126, causing de-crosslinking reactions within the crosslinked overcoat layer 126 to form de-crosslinked regions 134 to a target second depth D₂. The de-crosslinked regions 134 may also be referred to as anti-spacers. In certain embodiments, the baking process may be a thermal process that is performed by heating the substrate 102 in a process chamber to a temperature between 50° C. and 300° C., in vacuum or under a gas flow. In an embodiment, the baking may be performed at a temperature less than 160° C. for fewer than 6 min. In some embodiments, the baking may be performed a temperature less than 130° C. for fewer than 2 min.

The second depth D₂ may be tuned by parameters of the baking process (such as, for example, a bake temperature and a bake duration) and material parameters (such as, for example, a polymer composition of the crosslinked overcoat layer 126 and an acid composition and an acid concentration in the first mandrels 122). In some embodiments, the second depth D₂ and the thickness TH of the overcoat layer 124 (see FIG. 1E) may be tuned such that the second depth D₂ is greater than the thickness TH. In such embodiments, the solubility-changing agent 130 (see FIG. 1G) diffuses from the top surfaces of the first mandrels 122 to a top surface of the crosslinked overcoat layer 126 (as indicated by arrows 132), such that top surfaces of the de-crosslinked regions 134 are exposed and are level with a top surface of the crosslinked overcoat layer 126.

Referring to FIG. 1I, a developing process is performed on the substrate 102 using a suitable developer. The suitable developer may comprise an organic solvent that is selective to the de-crosslinked regions 134 (see FIG. 1H). In some embodiments, a solubility of the de-crosslinked regions 134 in the suitable developer is greater than a solubility of the crosslinked overcoat layer 126 in the suitable developer and also greater than a solubility of the first mandrels 122 in the suitable developer. The developing process selectively removes the de-crosslinked regions 134 to form first and second openings 138 and 140 that expose the intermediate layer 104.

Remaining regions of the crosslinked overcoat layer 126 form a plurality of second mandrels 136, such that the first and second mandrels 122 and 136 form a mandrel pattern 144 on the substrate 102. In some embodiments, the first mandrels 122 have a first height H₁ and the second mandrels 136 have a second height H₂, with the second height H₂ being greater than the first height H₁. In some embodiments, a width of the second mandrels 136 increases as the second mandrels 136 extend away from the substrate 102. In such embodiments, the second mandrels 136 comprise overhang regions 146 that overhang the first and second openings 138 and 140.

In some embodiments, the mandrel pattern 144 comprises a plurality of mandrel patterns 142. Each mandrel pattern 142 comprises first and second mandrels 122 and 136, and first and second openings 138 and 140, with the first opening 138 being interposed between the first mandrel 122 and the second mandrel 136, and the second mandrel 136 being interposed between the first opening 138 and the second opening 140. The first mandrel 122 may have a fifth width W₅, the first opening 138 may have a sixth width W₆, the second mandrel 136 may have a seventh width W₇, and the second opening 140 may have a width W₈. In the illustrated embodiment, a ratio W₅:W₆:W₇:W₈ equals 1:1:1:1. In such embodiments, the mandrel pattern 144 may be also referred to as a 1:1:1:1 L/S pattern. In other embodiments, the ratio W₅:W₆:W₇:W₈ may be equal to 1:X:(3-2X):X, where X is the second depth D₂ as measured in units of the fifth width W₅, with X being in a range from 0 to 3/2. In some embodiments, the pattern of the mandrel pattern 144 may be tuned by tuning X (i.e., by tuning the second depth D₂). In an example in which X=1 (i.e., in which D₂=W₅), the mandrel pattern 144 is the 1:1:1:1 L/S pattern.

In some embodiments, the mandrel pattern 144 may be transferred into the intermediate layer 104. For example, the intermediate layer 104 may be etched by an anisotropic etching process, such as reactive ion etching (RIE), while using the mandrel pattern 144 as an etch mask. In various embodiments, a transferred pattern may be used to form a contact hole, a via, a metal line, gate line, isolation region, and other features useful in semiconductor fabrication.

Various embodiments of the present disclosure may be compositions comprising a monomer (that may subsequently be polymerized) or a polymer. FIGS. 2A and 2B thus illustrate a monomer composition 20 and a polymer composition 22, according to the respective embodiments. Components outlined with a solid line are present in a given composition, while those outlined with a dashed line may be present in some embodiments of that composition.

With reference to FIG. 2A, a monomer composition 20 comprises a monomer 202. The monomer 202 itself comprises a polymerizable unit 204 that in turn comprises an olefin 206 (a carbon-carbon double bond, C═C), a de-crosslinking structure 208, and a crosslinking structure 210. According to various embodiments, the monomer photoresist formulation 40 may further comprise an organic solvent 212 in which the monomer 202 is soluble, a photoinitiator 214, or a co-monomer 216 (which may subsequently copolymerize with the monomer 202). Some such embodiments may be a formulation for producing a corresponding polymer composition 22.

In various embodiments, the monomer composition 20 may further comprise additional co-monomers with different composition from the monomer 202 and the co-monomer 216, additional solvents compatible with the organic solvent 212 and the monomer 202, and the like. While embodiments enable advantageous crosslinking functionality through the crosslinking structure 210 without the need for separate small-molecule crosslinkers, the latter may also be included in certain embodiments.

With reference to FIG. 2B, a polymer composition 22 comprises a polymer 218. The polymer 218 itself comprises an organic backbone 220, a de-crosslinking structure 222, and a crosslinking structure 224. The polymer 218 is soluble in an organic solvent 228 selected for the purpose. In some embodiments, the organic solvent 228 may be part of the polymer composition 22, i.e., the polymer composition 22 may be an overcoat material in the sense described with reference to FIGS. 1A-1I. In other embodiments, the polymer composition 22 may omit the organic solvent 228.

In embodiments comprising a polymer 218 formed from more than one polymerizable molecule (i.e., a copolymer), the polymer composition 22 may further comprise a copolymer structure 226. According to various embodiments, the polymer composition 22 may also comprise a base quencher 230.

In various other embodiments, the polymer composition 22 may further comprise additional polymers soluble in the organic solvent 228 and having different composition from the polymer 218. In some embodiments, additional polymers may differ from the polymer 218 by a variation in copolymer structure 226. Other additional components of the polymer composition 22 may comprise additional solvents compatible with the organic solvent 228 and the polymer 218, additional small-molecule crosslinkers, and the like, according to embodiments.

An embodiment monomer composition 20 may have at least one corresponding embodiment polymer composition 22, depending on the underlying polymerization chemistry. Monomers may polymerize by various mechanisms, such as free-radical polymerization, metathesis polymerization (including ring-opening metathesis polymerization), vinylic addition, etc., according to embodiments. Polymerization of the olefin 206 of the monomer 202 by these mechanisms may produce a polymer with an organic backbone 220 with a hydrocarbon structure.

In some embodiments, the polymer composition 22 may comprise a polymer 218 formed from a monomer comprising a different polymerizable unit (and thus producing a different backbone structure) from monomer 202. Such embodiments may comprise polyurethanes, silicones, polythioethers, polyimides, polyethers, epoxy resins, or other classes of polymers comprising heteroatoms such as nitrogen, oxygen, silicon, or sulfur.

Some embodiments of the polymer composition 22 may comprise condensation polymers. Condensation polymers form by reactions between pairs of precursor molecules that do not necessarily polymerize in isolation, such that both molecules, one molecule, or neither molecule may be a monomer in the sense of also being a minimal repeat unit of the resulting polymer. In embodiments of the monomer composition 20 configured to form a condensation polymer, the monomer 202 may be a molecule that undergoes condensation reaction with itself to form the condensation polymer; a minimal repeat unit of the condensation polymer formed by the condensation reaction between two precursor molecules; or a precursor molecule comprising a structural unit of the minimal repeat unit of the condensation polymer (such that the co-monomer 216 may be the other precursor molecule, in embodiments).

As already described, a monomer 202 may comprise a polymerizable unit 204 (itself comprising an olefin 206), a de-crosslinking structure 208, and a crosslinking structure 210. The manner in which these components are connected within a given embodiment monomer 202 may influence the crosslinking properties of a corresponding embodiment polymer 218. In particular, for a reaction of the de-crosslinking structure 208 to cleave a crosslink formed by the crosslinking structure 210, these structures may be connected to the polymerizable unit 204 (or a corresponding organic backbone 220) in series, rather than in parallel or in a cycle. Several bonding schemes for the monomer 202 consistent with self-crosslinking and de-crosslinking of the corresponding polymer 218 are illustrated in FIG. 3, according to various embodiments.

One such scheme represents a bonded monomer 30, in which a polymerizable unit (PU) 302 is bonded to a de-crosslinking structure (DS) 306, which is bonded in turn to a crosslinking structure (CS) 310. The bonding between one or both pairs of these components may be (but is not required to be) indirect, arising from mutual covalent bonding to a first connector (FC) 304, a second connector (SC) 308, or both, as indicated by the dashed outlines of the connectors 304 and 308 in FIG. 3.

The connectors 304 and 308 may generically represent whatever groups of bonded atoms separate the other components, if any. In embodiments not including either connector, the bonding scheme may represent a directly bonded monomer 32.

In some embodiments, the polymerizable unit 302 and the de-crosslinking structure 306 may overlap, that is, they may share an atom (or multiple atoms, in certain embodiments). A bonding scheme representing an overlapped monomer 34 of this type comprises an overlap region 312 between these components. In some embodiments, the second connector 308 may still be interposed between the de-crosslinking structure 306 and the crosslinking structure 310. In certain embodiments omitting the second connector 308, the bonding scheme may instead represent an overlapped and directly bonded monomer 36.

The various monomers 30, 32, 34, and 36 (as well as the corresponding polymers) may fragment into two or more pieces by a de-crosslinking reaction that cleaves the de-crosslinking structure 306, separating the crosslinking structure 310 (or a crosslink formed by it) from the rest of the molecule. (See also the description of FIG. 9A below.) If a parallel or cyclic bond were to connect the crosslinking structure 310 to the polymerizable unit 302, cleavage of the de-crosslinking structure 306 would change the molecule without fragmenting it.

That said, the bonding schemes illustrated in FIG. 3 were selected for purposes of illustration and do not represent the only embodiments of the monomer 202 consistent with the present disclosure. Embodiments including no more than the five components of the bonded monomer 30 may correspond to 36 distinct bonding schemes, given that successive pairs in the series may be either bonded or overlapped. Various other embodiments may comprise additional structural units that further expand the set of possibilities.

Various embodiments of the monomer composition 20 and the polymer composition 22 may be understood in more detail with reference to FIGS. 4, 5, and 12B, which illustrate monomers, co-monomers, and other structural units together with corresponding polymers and copolymer structures.

In some embodiments, and with reference to FIGS. 4 and 5, the polymerizable unit 204 may be a hydrocarbacrylate unit 502 with a pendant hydrocarbyl group R′. (A hydrocarbyl group comprises a single open valence and is obtained by removing a hydrogen atom from a hydrocarbon). The hydrocarbacrylate unit 502 may be derived from a generic hydrocarbacrylate 402 by removing an R group from the ester oxygen.

Some embodiments may comprise a hydrocarbacrylate unit 502 derived from an acrylate (R′=—H), such as methyl acrylate (R=CH₃, R′=—H). Other embodiments may comprise a hydrocarbacrylate unit 502 derived from a methacrylate (R′=CH₃), such as n-butyl methacrylate (R=—(CH₂)₃CH₃, R′=—CH₃).

In still other embodiments, and with further reference to FIGS. 4 and 5, the polymerizable unit 204 may be any of the styrenic units 506, 508, and 510 derived from styrene 404. For styrene 404, positional numbering on the benzene ring begins at 1 (the carbon with the vinyl group) and may increase counterclockwise, such that the 2^{nd}/6^{th}, 3^{rd}/5^{th}, and 4^{th} positions are respectively (and equivalently) referred to as ortho, meta, and para positions. Accordingly, the styrenic units 506, 508, and 510 may respectively be termed an ortho-styrenic unit, a meta-styrenic unit, and a para-styrenic unit.

In some embodiments, functionalization of styrene 404 and the corresponding polymerizable unit 204 may be desirable for the purpose of tuning polymer properties. Functionalized styrenes may include 4-chlorostyrene 406 or 4-hydroxystyrene (4-vinylphenol) 408, which may in turn correspond to polymerizable units (not illustrated) with the appropriate substitution at the para position and an open valence at either the ortho or meta position.

A co-monomer 216 of the monomer composition 20 may include a hydrocarbacrylate 402 (such as n-butyl acrylate or n-butyl methacrylate, R=—CH₂CH₂CH₂CH₃, and R′=—H or —CH₃) or a styrenic co-monomer like styrene 404, 4-chlorostyrene 406, or 4-hydroxystyrene 408. Similarly, and with reference to FIG. 12B, a polymer composition 22 may comprise a copolymer structure 226 such as polymerized n-butyl acrylate 1206 or n-butyl methacrylate 1208, polymerized styrene 1210, polymerized 4-chlorostyrene 1212, or polymerized 4-hydroxystyrene 1214. In each of the structures depicted, m may be any positive integer, and stars at either side may indicate an end group or a neighboring block of a copolymer structure, according to various embodiments.

The crosslinking structure 210 or 224 present in a monomer 202 or a polymer 218 may be activatable by a thermal or photochemical activating trigger, such as a crosslinking bake or exposure to an actinic radiation. The particular trigger and the nature of any crosslink formed may be determined by the detailed chemistry of the crosslinking structure 210 or 224, namely, by the types of atom involved in the crosslinking reaction and the connections between them. According to various embodiments, the crosslinking structure 210 or 224 may be any chemical functionality configured to respond to a thermal or photochemical activation and to generate a reactive intermediate that may form at least one bond between a pair of atoms, i.e., a crosslink. In various embodiments, the pair bond formed by the reactive intermediate may be between a pair of heavy atoms, such as a C—C, C—N, or C—O bond.

In various embodiments, the crosslinking structure 210 or 224 may comprise a diazo group (C═N₂). Without committing to any specific mechanism for crosslinking in particular embodiments, FIG. 6A illustrates crosslinking chemistry of a generic diazo-containing molecule 602 comprising organyl groups R and R′, which may be any organic substituent groups having open valences for bonding to the diazo carbon, according to various embodiments.

The generic diazo-containing molecule 602 may be represented in more detail by a set of resonant Lewis structures with varying bonding arrangements and formal charges. A major resonance structure 604 comprises C═N and N═N double bonds; a minor resonance structure 606 is more revealing of the chemistry of the diazo group, however, in that it shows the diazo group comprising a molecule of nitrogen (N₂) bonded to a negatively charged carbon. Fragmenting the carbon-nitrogen bond to release the diazo group (nitrogen molecule) may produce a reactive carbon capable of crosslinking.

Some diazo-containing molecules decompose spontaneously at room temperature or with gentle heating. In various embodiments, a crosslinking structure 210 or 224 comprising a diazo group may be stable at temperatures below 80° C.; in some embodiments, the crosslinking structure 210 or 224 may be stable at temperatures below 100° C. Stabilization of the diazo group may be achieved in certain embodiments by selecting the groups R and R′ to include an electron-withdrawing group (such as an ester —(C═O) OR, a keto group —(C═O)R, or a cyano group —CN) and an electron-donating group (such as a phenyl group or an alkyl group).

In some embodiments, the stabilized diazo functionality may be or comprise an α-phenyl diazo ester 612 like that illustrated in FIG. 6B. In other embodiments, the phenyl group of the α-phenyl diazo ester 612 may further comprise a substituent X at the para position relative to the diazo group rather than a hydrogen atom, enabling tuning of an absorption maximum of the α-phenyl diazo ester 612. In some embodiments, a para substituent X may comprise an electron-withdrawing group (EWG) that tunes the absorption maximum to longer wavelengths or an electron-donating group (EDG) that tunes the absorption maximum to shorter wavelengths.

In some embodiments, the para substituent X may be an EWG like a halogen atom, such as F, Cl, Br, or I; a haloalkyl group, such as a fluoroalkyl group —CₖH₂ₖ₋ₗ₊₁F₁ with positive integers k≥1 and (1≤l≤2k+1), wherein the fluorine atoms may be replaced by other halogens in any number and combination to yield other valid haloalkyls; a cyano group (—CN); or a nitro group (—NO₂). In other embodiments, the para substituent X may be an EDG, such as an alkoxy group (—OCₖH₂ₖ₊₁ with positive integer k≥1). In certain embodiments, the para substituent X may be a methoxy group (X=—OMe=—OCH₃).

In some embodiments, the absorption maximum of the diazo functionality of the diazo-containing molecule 602 may be tuned such that the actinic radiation may not trigger other crosslinking or de-crosslinking chemistry, such that it proceeds by an orthogonal mechanism. In other embodiments, the diazo-containing molecule 602 may crosslink by an orthogonal mechanism without any deliberate tuning.

With further reference to FIG. 6A, heating (A) the diazo-containing molecule 602 or exposing it to an actinic radiation (hv) may activate release of the diazo group (nitrogen molecule), forming a reactive carbene 608 that readily inserts into a C—H bond to form a crosslinked molecule 610. Diazo-based crosslinking chemistry is an advantageous new feature of these embodiments.

In various embodiments, and as illustrated in FIG. 7, the crosslinking structure 210 or 224 may instead comprise a benzophenone 702. Without committing to any specific mechanism for crosslinking in particular embodiments, FIG. 7 illustrates crosslinking chemistry of benzophenone 702, in which an actinic radiation (hv) triggers formation of a reactive biradical intermediate 704 that may then insert into a C—H bond to form a crosslinked molecule 706.

In some embodiments, the benzophenone 702 may further comprise a substituent X at the para position relative to the carbonyl (C═O), enabling tuning of an absorption maximum of the benzophenone 702. In some embodiments, the para substituent X may comprise a halogen atom, a haloalkyl group, a cyano group, a nitro group, or an alkoxy group, as described above. In certain embodiments, the para substituent X may be a methoxy group (X=—OMe=—OCH₃). In some embodiments, the absorption maximum of the benzophenone 702 may be tuned such that the actinic radiation may not trigger other crosslinking or de-crosslinking chemistry, such that it proceeds by an orthogonal mechanism. In other embodiments, the benzophenone 702 may crosslink by an orthogonal mechanism without any deliberate tuning.

As with the crosslinking structure 210 or 224, the de-crosslinking structure 208 or 222 present in a monomer 202 or a polymer 218 may be configured to respond to a trigger (or an activation). The particular trigger and the nature of any fragments formed by de-crosslinking may be determined by the detailed chemistry of the de-crosslinking structure 208 or 222, namely, by the types of atom involved in the de-crosslinking reaction and the connections between them. According to various embodiments, the de-crosslinking structure 208 or 222 may be any chemical functionality configured to be cleavable in the presence of acid (i.e., acid particles such as protons, H⁺) and to generate at least two fragments not connected by a bond. In various embodiments, the acid may be produced by triggering an acid generator, such as by exposing a photoacid generator to an actinic radiation or by heating a thermal acid generator. In other embodiments, the acid may be present as free acid particles in an adjacent structure, such as the first mandrels 122 of FIG. 1D.

In various embodiments, the de-crosslinking structure 208 or 222 may comprise an ester, including such as the generic ester 800 illustrated in FIG. 8A, wherein the groups R and R′ are organyl groups. In some embodiments, the group R may comprise the polymerizable unit 204 or organic backbone 220 of a respective monomer 202 or polymer 218, while the group R′ may comprise the crosslinking structure 210 or 224. In other embodiments, the positions of those structures may be swapped.

In some embodiments, and as illustrated in FIG. 8A, the ester 800 may be configured to cleave by acid-catalyzed hydrolysis, producing a carboxylic acid 802 and an alcohol HOR′ and also separating the polymerizable unit 204 or organic backbone 220 from the crosslinking structure 210 or 224. In some embodiments, hydrolysis of the ester 800 may proceed by a substitution mechanism. In other embodiments, the ester oxygen may be bonded to a sufficiently bulky group R′ that cleavage by acid-catalyzed elimination chemistry may be preferred.

Some of the latter embodiments may comprise a bond between an oxygen atom (the ester oxygen) and a tertiary carbon atom (a carbon atom bonded to three other carbons), as illustrated in FIG. 8B for a tert-butyl ester 804. Esters comprising a bond between an oxygen atom and a tertiary carbon atom may also be referred to as “tertiary-carbon esters.” In the illustrated embodiment, acid cleavage of the tert-butyl ester 804 produces the carboxylic acid 802 and isobutylene 806. In other embodiments, such as those comprising a less symmetrical group R′, a mixture of fragments may be produced. In some such embodiments, Zaitsev's rules indicate that terminal alkene fragments such as isobutylene 806 may be minor fragmentation products.

In some embodiments, a tertiary-carbon ester may be bulkier than the tert-butyl ester 804. For example, a methyl group of the tert-butyl ester 804 may be substituted with an ethyl group; an n-propyl or isopropyl group; an n-butyl, isobutyl, sec-butyl, or tert-butyl group; or higher alkyl groups. Substitution of the methyl group in this fashion may reduce the activation energy for elimination and tune the sensitivity of the de-crosslinking structure 208 or 222 to the presence of acid.

In various other embodiments, the de-crosslinking structure 208 or 222 may comprise an acid-cleavable acetal 808 or hemiacetal 810A or 810B, as illustrated in FIG. 8C, wherein the groups R¹-R⁴ are organyl groups. In some embodiments, the group R¹ may comprise the polymerizable unit 204 or organic backbone 220 of a respective monomer 202 or polymer 218, while the group R² may comprise the crosslinking structure 210 or 224. In other embodiments, those structures may respectively be part of other pairs of groups drawn without replacement from the set {R¹, R², R³, R⁴}; when the pair selected is {R³, R⁴}, either group (or both) may comprise additional de-crosslinking functionality.

According to various embodiments, the acetal 808 and the hemiacetals 810A and 810B may interconvert with each other and with a carbonyl compound 812 (such as a ketone or aldehyde) in the presence of acid, producing a mixture of fragments, including alcohols HOR¹ and HOR². This fragmentation chemistry may separate the polymerizable unit 204 or organic backbone 220 from the crosslinking structure 210 or 224, providing de-crosslinking functionality. But because the de-crosslinking reactions illustrated in FIG. 8C may be reversed relatively easily by comparison with those in FIG. 8B, such that crosslinks may (re-)form, embodiments comprising the acetal 808 or hemiacetals 810A or 810B may also enable flexible crosslinking functionality at a single site.

For embodiments comprising a polymer 218 with distinct crosslinking and de-crosslinking functionalities, the overall process of crosslinking followed by de-crosslinking may be represented by a schematic like that in FIG. 9A. Note that some reference numerals are retained for structures also appearing in FIG. 3.

An overlapped and directly bonded polymer unit 90 may be part of a larger polymer strand, and it comprises an organic backbone (BB) 902, a de-crosslinking structure (DS) 306 that shares at least one atom with the backbone 902 (as indicated by an overlap region 904), and a crosslinking structure 310. Because intra-polymer crosslinking does not contribute directly to formation of a crosslinked polymer network, a nearby partner molecule 906 may be a separate polymer, according to embodiments.

Crosslinking of the polymer unit 90 with the partner molecule 906 may be triggered by any of the means described above, such as thermal or photochemical diazo loss or photochemical benzophenone radical formation, according to embodiments. The resulting crosslink is depicted as a wavy bond 908.

De-crosslinking, such as de-crosslinking by acid cleavage of a bulky ester as in FIG. 8B, may then fragment the backbone 902 and the de-crosslinking structure 306, such that a detached linker (DL) 910 and crosslinking structure 310 remain attached to the partner molecule 906. The de-crosslinked partner 92 is no longer bonded to the backbone 902 or its parent polymer.

A specific embodiment of this self-crosslinking and de-crosslinking process is illustrated in FIG. 9B, which depicts one unit of polymerized 4-(2-diazo-2-phenylacetoxy)-2-methylbutan-2-yl methacrylate (tBuDAZ) 912. Crosslinking to a partner by thermal or photochemical diazo loss may yield a structure like the crosslinked unit 914. De-crosslinking by acid cleavage then produces two fragments, a methacrylic acid polymer unit 916 and a detached partner 918 comprising an isobutylene derivative. Note that the detached partner 918 may be produced as a mixture of constitutional isomers with different placement of the double bond, according to the details of its elimination chemistry.

Advantageous properties of embodiment monomers and polymers can be illustrated with reference to a monomer with systematic name 4-(2-diazo-2-phenylacetoxy)-2-methylbutan-2-yl methacrylate (tBuDAz) and its copolymers with n-butyl methacrylate (n-BuMA). The tBuDAz monomer corresponds to monomer 1002 of FIG. 10A with R being a methyl group (—CH₃) and X being a hydrogen atom (H), according to an embodiment.

The inventors synthesized tBuDAz from phenylacetic acid (PA), 3-methyl-1,3-butanediol (MBD), and methacryloyl chloride (MAC) by a three-step process: PA and an excess of MBD were coupled using 1-ethyl-3-(3-dimethylaminopropyl) carbodiimide (EDC) to form an intermediate ester (IME); the IME was transesterified with MAC using catalytic triethylamine (TEA) to form a diazo-less intermediate (DLI); and a diazo group was introduced into the DLI by Regitz diazo transfer.

Solvent extractions were sufficient to purify the IME after the first step. After the second and third steps, flash column chromatography was performed using hexane:ethyl acetate eluents with an additional 5% by volume of TEA included to suppress cleavage of the tertiary-carbon ester by acidity of the silica column. A solid orange product was obtained that is easily handled and readily soluble in a variety of organic solvents.

The identity of the product as tBuDAz was confirmed by ¹H nuclear magnetic resonance (NMR); in particular, a methylene proton (CH₂) peak observed in the NMR spectrum of the DLI is absent from the tBuDAz spectrum due to replacement of the associated protons by the diazo group. A Fourier-transform infrared (FTIR) spectrum of the product exhibited a strong diazo stretching peak at 2084 cm⁻¹, consistent with the product being tBuDAz.

The inventors also synthesized copolymers of tBuDAz and n-butyl methacrylate (n-BuMA) 1208 from mixtures of n-BuMA and tBuDAz by thermal free-radical polymerization using an azobisisobutyronitrile (AIBN) initiator. The polymerization was performed at a relatively low temperature (60° C.) and for a relatively long period (6-8 h) in order to suppress diazo release, which may be significant at temperatures at or above 100° C.

By varying the mole fractions of n-BuMA and tBuDAz, the inventors synthesized poly(n-BuMA-co-tBuDAz) copolymers with tBuDAz abundances of 7.5% and 14.5% (about 13:1 and about 7:1 n-BuMA:tBuDAz, respectively). In some embodiments, tBuDAz abundances as low as 5% (about 20:1) may still enable advantageous properties; higher abundances may also be used in some embodiments. For example, various embodiment copolymers may comprise tBuDAz abundances between 2% and 30% (between about 50:1 and about 3:1 co-monomer: tBuDAz, respectively).

The inventors determined the conversion of the polymerization and tBuDAz abundances in the copolymers by ¹H NMR. (For example, conversion of tBuDAz in the synthesis of a 7.5% copolymer was nearly 70% after 5 h and over 80% after 8 h.) They further confirmed retention of the diazo group—suppression of crosslinking by diazo loss during the polymerization—by observation of a strong diazo stretching peak at 2085 cm⁻¹ in an FTIR spectrum of the copolymer and by the lack of a shoulder in the high-molecular weight region of a size-exclusion chromatogram obtained by gel-permeation chromatography.

Having synthesized tBuDAz monomers and polymers, the inventors performed crosslinking and de-crosslinking tests in order to identify suitable conditions, especially with regard to crosslinking bake (CB) and post-exposure (de-crosslinking) bake (PEB) conditions. In these test embodiments, methyl isobutyl carbinol 1406 (see FIG. 14) was used as the development solvent; in other embodiments, other organic solvents may be used, such as those described below with further reference to FIG. 14.

In the inventors' crosslinking tests, 300 mm wafer samples were spin coated with embodiment polymer compositions (7.5% and 14.5% tBuDAz copolymerized with n-BuMA). Crosslink bakes (CBs) were then performed on the wafer samples for a range of bake temperatures (100° C.-120° C., with a step size of 10° C.) and bake times (5 min, 10 min, or 25 min) to trigger diazo loss and crosslinking (see FIG. 6A). The effectiveness of the crosslinking was quantified by comparing overcoat film thicknesses obtained from ellipsometry for each sample before and after a 30 s MIBC dip.

Initial film thicknesses for poly(n-BuMA-co-7.5% tBuDAz) were about 150 nm for samples baked at the two higher temperatures, with slightly thinner films obtained at 100° C. (about 130 nm). Unbaked samples were confirmed to develop completely after MIBC dip-in. Near-quantitative retention of the baked films was observed at all three bake temperatures for a 25 min bake time, but shorter bakes (e.g., 5 min or less) may be most compatible with throughput and efficiency requirements for semiconductor manufacturing on the front end of the line.

Under this stricter constraint, the inventors observed about 30% retention of films baked at 100° C., about 70% retention of films baked at 110° C., and near-quantitative retention of films baked at 120° C. Intermediate retention was observed after 10 min bake for the films prepared at lower temperature.

Initial film thicknesses for poly(n-BuMA-co-14.5% tBuDAz) were more consistent across bake conditions but thinner on average, about 130 nm. Complete development of unbaked samples and near-quantitative retention of films baked for 25 min were observed again, as was substantial film loss (about 50%) for samples baked under the stricter 5 min condition at 100° C. But film retention was near-quantitative for samples baked for 5 min at both higher temperatures, indicating higher-density crosslinking in copolymers initially comprising more diazo groups.

The inventors tested crosslinking further by performing dynamic development on several sample wafers coated with about 60 nm of poly(n-BuMA-co-7.5% tBuDAz). A sample baked for 5 min at 110° C., sprayed with MIBC for 10 s, and dried for 60 s at 90° C. exhibited about 15% film loss. Samples baked for 5 min at 120° C., by contrast, exhibited near-quantitative film retention, even under more aggressive development conditions including a second 10 s spray cycle.

The inventors performed a separate test of the kinetics of diazo release (and thus of crosslinking) by measuring the FTIR spectrum of sample wafers coated with poly(n-BuMA-co-7.5% tBuDAz) before and after baking for up to 25 min and at bake temperatures of 100° C., 120° C., and 140° C. By comparing the integrated intensity of the diazo stretch feature around 2084 cm⁻¹ in the spectrum, the percentage diazo release (and thus of crosslinking) can be quantified.

After 25 min of baking at 100° C., the FTIR spectrum indicated only about 40% diazo release. By contrast, diazo release is near-quantitative within 5 min of baking at 140 C, with intermediate results obtained from baking at 120 C (about 50% diazo release after 5 min and near-quantitative release after 25 min).

Because the previous crosslinking tests indicated that near-quantitative film retention may be achieved even at a bake temperature of 100° C. after 25 min, the inventors could infer that partial diazo release can nevertheless yield highly effective crosslinking. Temperature plays a role in diffusing the solubility-changing agent 130 (e.g., acid particles) in anti-spacer processes such as those described above, and may affect target depth D₂ and other parameters determining the overall mandrel pattern 144 formed on an outgoing substrate (as in FIG. 1I). The bake temperature and bake time may thus be selected to achieve desirable characteristics in the mandrel pattern 144; for example, in various embodiments, the crosslinking bake may be performed for a length of time between 15 s and 5 min at a temperature between 70° C. and 150° C. In one embodiment, the crosslinking bake may be performed for 60 s at a temperature of 120° C.

In addition to the crosslinking tests just described, the inventors also performed tests of de-crosslinking for embodiments comprising poly(n-BuMA-co-7.5% tBuDAz). In one such test, a polymer composition 22 comprising 5% total solid by weight was prepared and coated over sample wafers. While the solubility-changing agent 130 (e.g., acid particles) that promotes de-crosslinking in anti-spacer processes may typically be present in the first mandrels 122, as illustrated in FIGS. 1G and 1H, for these tests the solid fraction of the polymer composition 22 further included 10% of a photoacid generator (PAG). The overall loading of the PAG in the test composition was thus 0.5% by weight.

As in the crosslinking tests already described, the inventors prepared films on sample wafers using a range of crosslink bake times (5 min, 10 min, or 25 min) and crosslink bake temperatures (100° C.-120° C. with a 10° C. step size). Initial film thicknesses determined by ellipsometry were once again about 130 nm.

Having established a baseline, the inventors then exposed the samples to 254 nm UV radiation in order to activate the PAG and release acid particles, the total dose delivered to each sample being 50 mJ/cm². Acid diffusion and de-crosslinking was then promoted by a uniform post-exposure bake at 120° C. for 3 min. The effectiveness of de-crosslinking due to the PEB was quantified by measuring the film thickness again after a 30 s MIBC dip. In these tests, every sample exhibited near-total loss of film thickness (complete development), irrespective of CB time and CB temperature, indicating the effectiveness of acid cleavage of the tertiary-carbon ester (see, for example, FIG. 8B or FIG. 9B).

Because near-total de-crosslinking was achieved even after having performed a crosslinking bake for 25 min at 120° C., the inventors could infer that a milder post-exposure bake may nevertheless yield highly effective de-crosslinking. By contrast with the results of the 3 min PEB at 120° C., negligible film loss (and thus no de-crosslinking) was observed after a 60 s PEB at 100° C., but near-total loss was observed after the same bake time at 120° C., with an intermediate result (65% loss) at 110° C. The PEB temperature and time may thus be selected to achieve desirable characteristics in the mandrel pattern 144; for example, in various embodiments, the post-exposure bake may be performed for a length of time between 15 s and 5 min at a temperature between 70° C. and 150° C. In one embodiment, the post-exposure bake may be performed for 60 s at a temperature of 120° C.

The inventors performed a separate bilayer test of de-crosslinking to assess the UV dose dependence of the de-crosslinking. In this test, a sample wafer was coated with poly(n-BuMA-co-7.5% tBuDAz) and fully crosslinked by baking for 5 min at 120° C. A distinct acid-source layer comprising 5% by solid weight of triphenylsulfonium triflate in poly(tert-butyl acetate-co-4-hydroxystyrene) was then coated over the embodiment copolymer layer.

The overcoat-acid source bilayer was then exposed to 266 nm UV in a grayscale dose stripe starting with a maximum dose of 120 mJ, dropping to 0 mJ, and then gradually increasing to the maximum. After exposure (and thus activation of the PAG to release acid particles), the wafer was post-exposure baked for 3 min at 120° C. and dynamically developed by two 10 s sprays of MIBC. The inventors observed that full de-crosslinking occurred at a relatively low dose, between 10 mJ and 20 mJ, in accordance with an embodiment. In various embodiments, a dose of actinic radiation delivered to the substrate being patterned may be between 5 mJ and 120 mJ. In some embodiments, the dose of actinic radiation delivered may be 60 mJ or less.

Specific embodiment monomers and polymers are now described in more detail with reference to FIGS. 10A/10B, FIG. 11, and FIG. 12A. A first embodiment monomer 1002 corresponds to choosing the polymerizable unit 204 to be a methacrylate unit 1004, the de-crosslinking structure 208 to be a tertiary-carbon ester 1006 (an ester comprising a bond between an oxygen atom and a tertiary carbon atom) with a pendant group R, and the crosslinking structure 210 to be an α-phenyl diazo ester 1008 with a para substituent X.

In a first embodiment monomer 1002, pendant group R of the tertiary-carbon ester 1006 comprises a hydrocarbyl group, and the para substituent X may comprise a hydrogen atom or an electron-withdrawing group, such as a halogen atom, a haloalkyl group, a cyano group, a nitro group, or an alkoxy group. In certain embodiments, the para substituent X may be a methoxy group (X=—OMe=—OCH₃). In one embodiment corresponding to R=—CH₃ and X=H, the first embodiment monomer 1002 is 4-(2-diazo-2-phenylacetoxy)-2-methylbutan-2-yl methacrylate (tBuDAz).

A second embodiment monomer 1010 differs from the first only in the choice of crosslinking structure 210, namely, a benzophenone ester 1012. In one embodiment corresponding to R=—CH₃ and X=H, the second embodiment monomer 1010 is a benzophenone analog of tBuDAz.

As indicated by the boxes framing the monomers 1002 and 1010, they both correspond to the overlapped and directly bonded monomer 36 of FIG. 3, such that their self-crosslinking and de-crosslinking may be illustrated schematically by FIG. 9A. Note, however, that there may be some ambiguity in partitioning any given molecule. For example, choosing the boundaries of the tertiary-carbon ester 1006 (corresponding to the de-crosslinking structure 306) and the α-phenyl diazo ester 1008 (corresponding to the crosslinking structure 310) to omit bracketed atoms 1014 would map monomers 1002 and 1010 to the overlapped and bonded monomer 34 of FIG. 3, with the second connector 308 being a 1,2-ethanediyl unit.

FIG. 10B illustrates first and second embodiment polymers 1016 and 1020 corresponding to polymerization products of the first and second embodiment monomers 1002 and 1010. Note, however, that in some embodiments the embodiment polymers 1016 and 1020 might be synthesized directly from polymer precursors by coupling to one or more small molecules comprising the necessary crosslinking and de-crosslinking functionalities.

A first embodiment polymer 1016 corresponds to choosing the organic backbone 220 to be a methacrylate backbone 1018, the de-crosslinking structure 222 to be the tertiary-carbon ester 1006 (an ester comprising a bond between an oxygen atom and a tertiary carbon atom) with a pendant group R, and the crosslinking structure 224 to be the α-phenyl diazo ester 1002 with a para substituent X. A second embodiment polymer 1020 differs from the first only in the choice of crosslinking structure 224, namely, the benzophenone ester 1012. In each of the structures depicted, n may be any positive integer greater than 2, and stars at either side may indicate an end group (as may be determined by a choice of photoinitiator 214 in the monomer composition 20) or a neighboring block of a copolymer structure, according to various embodiments.

With reference to FIG. 11, other embodiment polymers may comprise a different organic backbone 220 from the methacrylate backbone 1018; as illustrated, a styrenic backbone 1104 may be selected instead, for example. The embodiment polymers of FIG. 11 may represent (respectively) an ortho-styrenic variant 1106, a meta-styrenic variant 1102, and a para-styrenic variant 1108 of the first embodiment polymer 1016.

As indicated by the framing boxes, all three styrenic variants correspond to the directly bonded monomer 32 of FIG. 3. Alternatively, the carbonyl and oxygen of the ester ((C═O) O) might be incorporated into the styrenic backbone to yield a 4-vinylbenzoate backbone, such that the styrenic variants map to the overlapped and directly bonded monomer 36 and FIG. 9A still illustrates the self-crosslinking and de-crosslinking of these polymers.

With reference to FIG. 12A, some embodiment polymers may further comprise a first copolymer structure 1202, a second copolymer structure 1204, or both. The corresponding embodiments may result from copolymerization of first embodiment monomer 1002 with n-butyl methacrylate; from synthetic coupling of one or more small molecules to a polymer precursor such as n-butyl methacrylate; or from any other suitable process.

As with the monomers 1002 and 1010, in the polymers 1016 and 1020 and in the copolymer structures 1202 and 1204, the pendant group R of the tertiary-carbon ester 1006 comprises a hydrocarbyl group, and the para substituent X may comprise a hydrogen atom; an electron-withdrawing group, such as a halogen atom, a haloalkyl group, a cyano group, or a nitro group; or an electron-donating group, such as an alkoxy group. In certain embodiments, the para substituent X may be a methoxy group (X=—OMe=—OCH₃). In embodiments corresponding to R=—CH₃ and X=H and omitting the copolymer structure 226, the polymers 1016 and 1020 may represent poly(4-(2-diazo-2-phenylacetoxy)-2-methylbutan-2-yl methacrylate) (poly(tBuDAz)) or a benzophenone variant thereof. Embodiments further comprising copolymer structures 1202 and 1204 may be poly(n-BuMA-co-tBuDAz)—with any desired abundance of co-monomers—or a benzophenone variant thereof. Other embodiments not illustrated may include terpolymers and higher copolymers, such as those comprising various combinations of the polymer structures illustrated in FIG. 10B, FIG. 11, and FIGS. 12A/12B.

As mentioned above with reference to FIGS. 2A and 2B, embodiments of the monomer composition 20 may comprise the organic solvent 212. Similarly, embodiments of the polymer composition 22 may comprise the organic solvent 228. According to various embodiments, suitable solvents may be any organic solvent with a boiling point above 110° C. at 1 bar and with relative permittivity below 40 for at least one temperature below 35° C. In some embodiments, and with reference to FIG. 14, the organic solvent 212 or 228 may be a conventional overcoat developer solvent such as 1-butanol 1402, isoamyl ether (IAE) 1404, methyl isobutyl carbinol (4-methyl-2-pentanol or MIBC) 1406, any combination or admixture thereof, and the like.

According to various embodiments, the organic solvent 212 or 228 may be selected not to dissolve a target photoresist polymer, such as those that may be used to form the first mandrels 122, so that the target mandrel pattern 144 is not blurred, damaged, or destroyed during development of the de-crosslinked regions 134 (see FIGS. 1H and 1I). Thus, an additional factor in determining the suitability of a given organic solvent for use in the monomer composition 20 or the polymer composition 22 may be a distance in Hansen solubility parameter space (HSP space) between the given organic solvent and the target photoresist polymer.

Hansen solubility parameter (HSPs) are a set of three parameters that may be used to estimate the solubility of materials, particularly polymers, in different solvents. The parameters are a dispersion parameter 8D, which quantifies van der Waals (dispersion) forces present in all molecules; a polar parameter 8P, which quantifies dipole-dipole interactions between polar molecules; and a hydrogen-bonding parameter δH, which quantifies the hydrogen-bonding interactions between molecules (if any).

The HSPs define a 3D space—Hansen space or HSP space—in which solvents and solutes can be mapped. A reference material (such as a target photoresist polymer) may be represented by a point in HSP space with coordinate S°=(δD°, δP°, δH°); a sphere surrounding that point may represent the space of all solvents (or various combinations or admixtures of solvents and other materials) within a chosen non-negative “distance” of the reference.

According to the basic chemical principle that “like dissolves like,” a reference point and a distance from that point in Hansen space defines a set of solvents more likely to dissolve the reference material than those solvents whose Hansen-space coordinates lie outside the sphere. In embodiments comprising a target photoresist polymer as the reference material, the organic solvent 212 (or the organic solvent 228) may thus be selected from the outlying set of solvents.

According to embodiments, reference HSP values may be those for a target photoresist polymer, which may be any conventional photoresist polymer used to form the first mandrels 122 of FIG. 1D, such as poly(methyl methacrylate), polystyrene, polyisoprene, SU-8 epoxy, and the like. The distance of a given organic solvent from the reference in Hansen space (the “Hansen distance”) may be calculated according to the equation

$${Dist}_{i} = \sqrt{4 {( δ D ° - δ {D}_{i} )}^{2} + {( δ P ° - δ {P}_{i} )}^{2} + {( δ H ° - δ {H}_{i} )}^{2}} , \qquad ( Equation 1 )$$

where Distᵢ represents the Hansen distance of the organic solvent i (with Hansen parameters labeled thus) from the reference material.

According to embodiments, an individual organic solvent 212 or 228 may be selected if the Hansen distance of that solvent from the target photoresist polymer is greater than 8, i.e., if the organic solvent 212 or 228 lies outside of a sphere of radius 8 surrounding the reference point S° in Hansen space. A greater distance may generally indicate less similarity to the reference and thus lower solubility of the target photoresist polymer. As such, in some embodiments a Hansen distance used to select an organic solvent 212 or 228 may be greater than 9; greater than 10; greater than 11; and so on.

In some embodiments, a mixture of miscible solvents {i} may be considered for use in the monomer composition 20 or the polymer composition 22. In these embodiments, a weighted average of Hansen parameters may be used to characterize the mixture. For example, a Hansen dispersion parameter for a mixture may be calculated as δDₘᵢₓ=ΣᵢfᵢδDᵢ, where fᵢ is the volume fraction of solvent i in the mixture, and the other parameters may be averaged according to similar formulas. The Hansen distance of the mixture from the reference may then be determined from Equation 1, i.e., by evaluating Distₘᵢₓ. According to these embodiments, a mixture of miscible solvents {i} may thus be selected if the Hansen distance of that mixture from the target photoresist polymer is greater than 8, or (in other embodiments) greater than 9, 10, 11, or another, larger integer.

As also mentioned above, and according to embodiments, the monomer composition 20 may comprise a photoinitiator 214. The photoinitiator 214 may be a Norrish type I photoinitiator forming radicals by cleavage (such as azobisisobutyronitrile (AIBN), an α-hydroxyketone, or a phosphine oxide); a Norrish type II photoinitiator forming radicals by proton abstraction (such as camphorquinone, a benzophenone, or a thioxanthone); a cationic photoinitiator sharing features of both Norrish types (such as an iodonium or sulfonium salt); or any other suitable photoinitiator. In embodiments comprising Norrish type II or cationic photoinitiators, the monomer composition 20 may additionally comprise a co-initiator (proton donor) such as an ether, amine, alcohol, or thiol.

Some photoinitiators may also form radicals on heating, such that they may be used in some embodiments to produce a polymer by thermal free-radical polymerization. In an embodiment, one such thermal initiator may be AIBN.

According to various embodiments, the polymer composition 22 may further comprise a base quencher 230. The base quencher 230 may scavenge the solubility-changing agent 130 (i.e., acid particles) during the post-exposure bake and diffusion process depicted in FIGS. 1G and 1H, thereby enabling finer control over the number of protons available for de-crosslinking (as well as their mean free path before being scavenged). In other words, the base quencher 230 may help to tune the target depth D₂ and the sharpness of the resulting mandrel pattern 144.

Any base quencher 230 soluble in the organic solvent 228 may be selected. In some embodiments, the base quencher 230 may comprise ammonium, an amine, an amide, a piperidine, a piperazine, a pyridine, a pyrimidine, or the like, with or without substitution. In certain embodiments, and as illustrated in FIG. 13, the base quencher may comprise 1,8-diazabicyclo[5.4.0]undec-7-ene (DBU) 1302, 1-piperidineethanol (1-PE) 1304, tetramethylammonium hydroxide (TMAH) 1306, or tetrabutylammonium hydroxide (TBAH) 1308.

In some embodiments, the base quencher 230 may be a photodecomposable quencher (PDQ) that releases base or otherwise becomes activated by exposure to an actinic radiation. In some such embodiments in which the first mandrels 122 comprise a photoacid generator (PAG), the PDQ may be selected for process compatibility with the PAG (e.g., sensitivity to the same or overlapping wavelengths of light), such that they may be activated simultaneously during the same exposure step (such as that illustrated in FIG. 1G). In other such embodiments, the PDQ may be selected to be triggered by a wavelength of light well-separated from the wavelength that triggers the PAG, such that they may be activated separately (e.g., by distinct exposure steps).

In some embodiments, a photodecomposable quencher chosen as the base quencher 230 may be a nonionic PDQ such as a carbamate or an O-acyloxime. In various other embodiments, the base quencher 230 may be an ionic PDQ comprising one or more cations and one or more anions, i.e., a salt. Cations in an ionic PDQ may comprise sulfonium-based cations such as triphenylsulfonium; iodonium-based cations such as diphenyliodonium; quaternary ammonium cations such as trimethylammonium; or any other suitable cation. In some embodiments, anions in an ionic PDQ may comprise an anionic base, such as free base (—OH or hydroxide). In one such embodiment, the ionic PDQ may be triphenylsulfonium hydroxide.

In various embodiments comprising an anionic base, the anionic base may be a conjugate base A⁻ of an acid HA, as related by the generic acid-dissociation equilibrium

$$H A ( aq ) + {H}_{2} O ( ℓ ) ⇋ {H}_{3} {O}^{+} ( aq ) + {A}^{-} ( aq ) {K}_{a} = [ {H}_{3} {O}^{+} ] [ {A}^{-} ] / [ H A ] , \qquad ( Equation 2 )$$

wherein the acid-dissociation equilibrium constant Kₐ is conventionally defined in terms of aqueous concentrations of the acid, the conjugate base, and the hydronium ion H₃O⁺. The negative base-10 logarithm pKₐ=−log₁₀ Kₐ is a convenient figure of merit for acid strength, with stronger acids having smaller (more negative) pKₐ and weaker acids having larger (more positive) pKₐ.

In embodiments comprising a PDQ with an anionic base, an additional criterion for compatibility with the PAG may be that the acid HA should have pKₐ^{HA} larger than that of the acid generated by the PAG, pKₐ_{_{PAG}}. The greater (more positive) the difference ΔpKₐ=(pKa^{HA}−pKₐ^{PAG}), the more completely the PAG acid may protonate the anionic base A. As such, a greater pKa difference may correlate with a stronger quenching effect on the target depth D₂ (see FIG. 1H) and thus a stronger influence on the mandrel pattern 144 (see FIG. 1I).

The suitability of a given anionic base for an embodiment ionic PDQ may be determined in part by a corresponding choice of PAG. In certain embodiments in which the PAG generates a superacid, the ionic PDQ may even comprise a compound that would function as a PAG in a different chemical environment. For example, a PAG generating triflic acid (pKa≈−15) may be quenched by an ionic PDQ comprising 10-camphorsulfonate (conjugate to camphorsulfonic acid having pKa≈1.2), even though triphenylsulfonium 10-camphorsulfonate may be a PAG in isolation. Stronger quenching may be achieved by using anionic bases conjugate to even weaker acids, such as borate (conjugate to boric acid having pKa≈9.2)

In embodiments comprising both an ionic PDQ and an ionic PAG, the PDQ and the PAG may be chosen such that ion exchange is suppressed or has a limited effect on properties such as solubility of the PDQ or PAG, quantum yield of acid or base, and diffusion rate of acid or base.

Still other components may be part of the polymer composition 22, in various embodiments. For example, the polymer composition 22 may further comprise a plasticizer soluble in the organic solvent 228 and chosen to improve the mechanical properties of a corresponding overcoat layer 124. In some embodiments, the plasticizer may comprise a phthalate, an isophthalate, or a terephthalate.

The process flows described with reference to FIGS. 1A-1I may represent various embodiments of a more general method of patterning a substrate, as illustrated by a flow chart in FIG. 15.

In box 1501, a plurality of first mandrels is formed over a substrate, resulting in a structure similar to that illustrated in FIG. 1D. (In some embodiments, the photoresist patterning and trimming processes described with reference to FIGS. 1A-1C may be used.) Optionally, in box 1511, acid is supplied to the first mandrels from an acid-source layer, as described above. Next, in box 1502, an overcoat layer is coated over the plurality of first mandrels, as illustrated in FIG. 1E. In various embodiments, the overcoat layer may be coated from a polymer composition such as those illustrated in FIG. 2B.

In box 1503, a crosslinking reaction is induced within the overcoat layer that renders it insoluble to a predetermined solvent and forms a crosslinked overcoat layer, resulting in a structure similar to that illustrated in FIG. 1F. In some embodiments, the crosslinking reaction may be a thermally activated reaction, such as C—H insertion following diazo loss (as illustrated for embodiments in FIG. 6A), or a photochemically activated reaction, such as radical crosslinking by benzophenone (as illustrated for other embodiments in FIG. 7). In embodiments comprising a thermal crosslinking reaction, a crosslinking bake may also be performed as described above.

Next, in box 1504, the substrate is exposed to an actinic radiation to generate a plurality of acid particles within the plurality of first mandrels, as illustrated for embodiments in FIG. 1G. Then, in box 1505, the plurality of acid particles is diffused from the plurality of first mandrels into portions of the crosslinked overcoat layer, as illustrated for embodiments in FIG. 1H. This diffusion process may comprise a post-exposure (de-crosslinking) bake performed as described above.

In box 1506, a de-crosslinking reaction is induced within the portions of the crosslinked overcoat layer to form de-crosslinked regions, as further illustrated for embodiments in FIG. 1H. Unmodified regions of the crosslinked overcoat layer thus form a plurality of second mandrels. Then, in box 1507, the de-crosslinked regions are removed selectively. The plurality of first mandrels and the plurality of second mandrels together form a mandrel pattern over the substrate, yielding an outgoing substrate like that illustrated in FIG. 1I.

Example embodiments of the invention are described below. Other embodiments can also be understood from the entirety of the specification as well as the claims filed herein.

Example 1. A composition for patterning substrates includes a monomer. The monomer includes a polymerizable unit, a thermally or photochemically activatable crosslinking structure, and an acid-cleavable de-crosslinking structure. The polymerizable unit includes an olefin.

Example 2. The composition of example 1, where the polymerizable unit is an acrylate unit, a methacrylate unit, or a styrenic unit.

Example 3. The composition of one of examples 1 or 2, where the crosslinking structure includes a diazo group or a benzophenone.

Example 4. The composition of one of examples 1 to 3, where the de-crosslinking structure includes an ester, a hemiacetal, or an acetal.

Example 5. The composition of one of examples 1 to 4, where the polymerizable unit is an acrylate unit or a methacrylate unit, the crosslinking structure is an α-phenyl diazo ester, and the de-crosslinking structure is a tertiary-carbon ester.

Example 6. The composition of one of examples 1 to 5, where the polymerizable unit and the de-crosslinking structure share an atom.

Example 7. The composition of one of examples 1 to 6, where the polymerizable unit and the crosslinking structure are bonded to the de-crosslinking structure.

Example 8. The composition of one of examples 1 to 7, where the monomer is monomer 1002, where the polymerizable unit is a methacrylate unit, the crosslinking structure includes an α-phenyl diazo ester, the de-crosslinking structure includes a tertiary-carbon ester, a pendant group R includes a hydrocarbyl group, and a para substituent X includes a hydrogen atom, a halogen atom, a haloalkyl group, a cyano group, a nitro group, or an alkoxy group.

Example 9. The composition of one of examples 1 to 7, where the monomer is monomer 1010, where the polymerizable unit is a methacrylate unit, the crosslinking structure includes a benzophenone, the de-crosslinking structure includes a tertiary-carbon ester, a pendant group R includes a hydrocarbyl group, and a para substituent X includes a hydrogen atom, halogen atom, a haloalkyl group, a cyano group, a nitro group, or an alkoxy group.

Example 10. The composition of one of examples 1 to 9, where the monomer is configured to be polymerized by free-radical polymerization, condensation polymerization, or metathesis polymerization.

Example 11. The composition of one of examples 1 to 10, where the polymerizable unit, the crosslinking structure, and the de-crosslinking structure react by orthogonal mechanisms.

Example 12. A composition for patterning substrates includes a polymer that is soluble in an organic solvent. The polymer includes an organic backbone, a thermally or photochemically activatable crosslinking structure, and an acid-cleavable de-crosslinking structure.

Example 13. The composition of example 12, where the polymer includes a structure 1016, where the organic backbone is a methacrylate backbone, the crosslinking structure includes an α-phenyl diazo ester, the de-crosslinking structure includes a tertiary-carbon ester, a pendant group R includes a hydrocarbyl group, a para substituent X includes a hydrogen atom, a halogen atom, a haloalkyl group, a cyano group, a nitro group, or an alkoxy group, and a positive integer n is greater than 2.

Example 14. The composition of one of examples 12 or 13, where the polymer includes a structure 1020, where the organic backbone is a methacrylate backbone, the crosslinking structure includes a benzophenone, the de-crosslinking structure includes a tertiary-carbon ester, a pendant group R includes a hydrocarbyl group, a para substituent X includes a hydrogen atom, a halogen atom, a haloalkyl group, a cyano group, a nitro group, or an alkoxy group, and a positive integer n is greater than 2.

Example 15. The composition of one of examples 12 to 14, where the polymer includes a structure 1108, a structure 1102, or a structure 1106, where the organic backbone is a styrene backbone, the crosslinking structure includes an α-phenyl diazo ester, the de-crosslinking structure includes a tertiary-carbon ester, a pendant group R includes a hydrocarbyl group, a para substituent X includes a hydrogen atom, a halogen atom, a haloalkyl group, a cyano group, a nitro group, or an alkoxy group, and a positive integer n is greater than 2.

Example 16. The composition of one of examples 12 to 15, where the polymer further includes a first copolymer structure 1202, a second copolymer structure 1204, or both, where a pendant group R includes a hydrocarbyl group, and a para substituent X includes a hydrogen atom, a halogen atom, a haloalkyl group, a cyano group, a nitro group, or an alkoxy group.

Example 17. The composition of one of examples 12 to 16, where the polymer further includes polymerized n-butyl acrylate, polymerized n-butyl methacrylate, polymerized styrene, polymerized 4-chlorostyrene, or polymerized 4-hydroxystyrene.

Example 18. The composition of one of examples 12 to 17, further including a base quencher soluble in the organic solvent.

Example 19. The composition of one of examples 12 to 18, where the base quencher is 1,8-diazabicyclo[5.4.0]undec-7-ene, 1-piperidineethanol, tetrabutylammonium hydroxide, or tetramethylammonium hydroxide.

Example 20. The composition of one of examples 12 to 19, where the organic solvent has a Hansen distance greater than 8 from a target photoresist polymer.

Example 21. A method of patterning a substrate includes forming a plurality of first mandrels over a substrate; coating an overcoat layer over the plurality of first mandrels, the overcoat layer being coated from a composition including a polymer and an organic solvent, the polymer including an organic backbone, a thermally or photochemically activatable crosslinking structure, and an acid-cleavable de-crosslinking structure; inducing a crosslinking reaction within the overcoat layer that renders the overcoat layer insoluble to a predetermined solvent and forms a crosslinked overcoat layer; exposing the substrate to an actinic radiation to generate a plurality of acid particles within the plurality of first mandrels; diffusing a portion of the plurality of acid particles from the plurality of first mandrels into portions of the crosslinked overcoat layer; inducing a de-crosslinking reaction within the portions of the crosslinked overcoat layer to form de-crosslinked regions, where unmodified regions of the crosslinked overcoat layer form a plurality of second mandrels; and selectively removing the de-crosslinked regions. The plurality of first mandrels and the plurality of second mandrels form a mandrel pattern over the substrate.

Example 22. The method of example 21, where the polymer includes a structure 1020, where the organic backbone is a methacrylate backbone, the crosslinking structure includes a benzophenone, the de-crosslinking structure includes a tertiary-carbon ester, a pendant group R includes a hydrocarbyl group, a para substituent X includes a halogen atom, a haloalkyl group, a cyano group, a nitro group, or an alkoxy group, and a positive integer n is greater than 2.

Example 23. The method of one of examples 21 or 22, where the polymer further includes a first copolymer structure 1202, a second copolymer structure 1204, or both, where a pendant group R includes a hydrocarbyl group, and a para substituent X includes a halogen atom, a haloalkyl group, a cyano group, a nitro group, or an alkoxy group.

Example 24. The method of one of examples 21 to 23, where inducing the crosslinking reaction includes baking at a temperature less than 130° C. for fewer than 6 min.

Example 25. The method of one of examples 21 to 24, where diffusing the portion of the plurality of acid particles includes baking at a temperature less than 130° C. for fewer than 6 min.

While this invention has been described with reference to illustrative embodiments, this description is not intended to be construed in a limiting sense. Various modifications and combinations of the illustrative embodiments, e.g., of FIGS. 1-15, as well as other embodiments of the invention, will be apparent to persons skilled in the art upon reference to the description. It is therefore intended that the appended claims encompass any such modifications or embodiments.

What is claimed is:

1. A composition for patterning substrates, the composition comprising:
a monomer comprising:
a polymerizable unit comprising an olefin;
a thermally or photochemically activatable crosslinking structure; and
an acid-cleavable de-crosslinking structure.

2. The composition of claim 1, wherein the polymerizable unit is an acrylate unit, a methacrylate unit, or a styrenic unit.

3. The composition of claim 1, wherein the crosslinking structure comprises a diazo group or a benzophenone.

4. The composition of claim 1, wherein the de-crosslinking structure comprises an ester, a hemiacetal, or an acetal.

5. The composition of claim 1, wherein the polymerizable unit is an acrylate unit or a methacrylate unit, the crosslinking structure is an α-phenyl diazo ester, and the de-crosslinking structure is a tertiary-carbon ester.

6. The composition of claim 1, wherein the polymerizable unit and the crosslinking structure are bonded to the de-crosslinking structure.

7. The composition of claim 1, wherein the monomer is 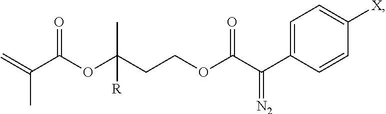
wherein the polymerizable unit is a methacrylate unit, the crosslinking structure comprises an α-phenyl diazo ester, the de-crosslinking structure comprises a tertiary-carbon ester, a pendant group R comprises a hydrocarbyl group, and a para substituent X comprises a hydrogen atom, a halogen atom, a haloalkyl group, a cyano group, a nitro group, or an alkoxy group.

8. The composition of claim 1, wherein the monomer is 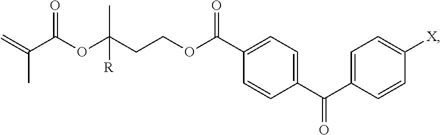
wherein the polymerizable unit is a methacrylate unit, the crosslinking structure comprises a benzophenone, the de-crosslinking structure comprises a tertiary-carbon ester, a pendant group R comprises a hydrocarbyl group, and a para substituent X comprises a hydrogen atom, halogen atom, a haloalkyl group, a cyano group, a nitro group, or an alkoxy group.

9. The composition of claim 1, wherein the polymerizable unit, the crosslinking structure, and the de-crosslinking structure react by orthogonal mechanisms.

10. A composition for patterning substrates, the composition comprising:
a polymer comprising:
an organic backbone;
a thermally or photochemically activatable crosslinking structure; and
an acid-cleavable de-crosslinking structure, the polymer being soluble in an organic solvent.

11. The composition of claim 10, wherein the polymer comprises a structure 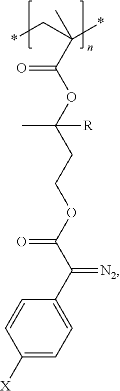
wherein the organic backbone is a methacrylate backbone, the crosslinking structure comprises an α-phenyl diazo ester, the de-crosslinking structure comprises a tertiary-carbon ester, a pendant group R comprises a hydrocarbyl group, a para substituent X comprises a hydrogen atom, a halogen atom, a haloalkyl group, a cyano group, a nitro group, or an alkoxy group, and a positive integer n is greater than 2.

12. The composition of claim 10, wherein the polymer comprises a structure 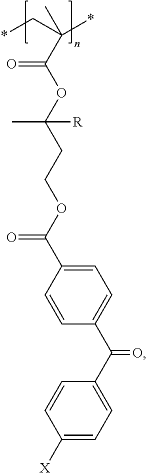
wherein the organic backbone is a methacrylate backbone, the crosslinking structure comprises a benzophenone, the de-crosslinking structure comprises a tertiary-carbon ester, a pendant group R comprises a hydrocarbyl group, a para substituent X comprises a hydrogen atom, a halogen atom, a haloalkyl group, a cyano group, a nitro group, or an alkoxy group, and a positive integer n is greater than 2.

13. The composition of claim 10, wherein the polymer comprises a structure 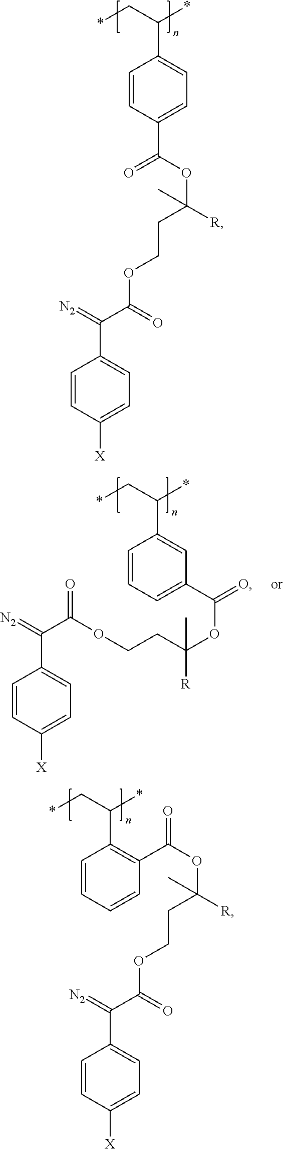
wherein the organic backbone is a styrene backbone, the crosslinking structure comprises an α-phenyl diazo ester, the de-crosslinking structure comprises a tertiary-carbon ester, a pendant group R comprises a hydrocarbyl group, a para substituent X comprises a hydrogen atom, a halogen atom, a haloalkyl group, a cyano group, a nitro group, or an alkoxy group, and a positive integer n is greater than 2.

14. The composition of claim 10, wherein the polymer further comprises a first copolymer structure 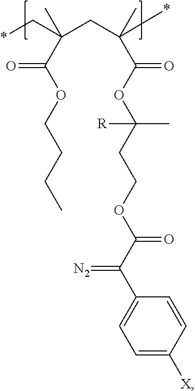
a second copolymer structure 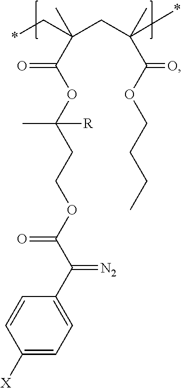
or both, wherein a pendant group R comprises a hydrocarbyl group, and a para substituent X comprises a hydrogen atom, a halogen atom, a haloalkyl group, a cyano group, a nitro group, or an alkoxy group.

15. The composition of claim 10, further comprising a base quencher soluble in the organic solvent, wherein the base quencher is 1,8-diazabicyclo[5.4.0]undec-7-ene, 1-piperidineethanol, tetrabutylammonium hydroxide, or tetramethylammonium hydroxide.

16. The composition of claim 10, wherein the organic solvent has a Hansen distance greater than 8 from a target photoresist polymer.

17. A method of patterning a substrate, the method comprising:
forming a plurality of first mandrels over a substrate;
coating an overcoat layer over the plurality of first mandrels, the overcoat layer being coated from a composition comprising:
a polymer comprising:
an organic backbone;
a thermally or photochemically activatable crosslinking structure; and
an acid-cleavable de-crosslinking structure; and
an organic solvent;
inducing a crosslinking reaction within the overcoat layer that renders the overcoat layer insoluble to a predetermined solvent and forms a crosslinked overcoat layer;
exposing the substrate to an actinic radiation to generate a plurality of acid particles within the plurality of first mandrels;
diffusing a portion of the plurality of acid particles from the plurality of first mandrels into portions of the crosslinked overcoat layer;
inducing a de-crosslinking reaction within the portions of the crosslinked overcoat layer to form de-crosslinked regions, wherein unmodified regions of the crosslinked overcoat layer form a plurality of second mandrels; and
selectively removing the de-crosslinked regions, wherein the plurality of first mandrels and the plurality of second mandrels form a mandrel pattern over the substrate.

18. The method of claim 17, wherein the polymer comprises a structure 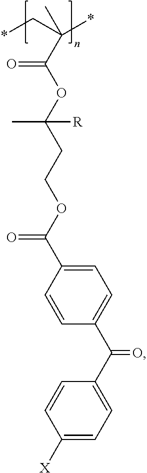
wherein the organic backbone is a methacrylate backbone, the crosslinking structure comprises a benzophenone, the de-crosslinking structure comprises a tertiary-carbon ester, a pendant group R comprises a hydrocarbyl group, a para substituent X comprises a halogen atom, a haloalkyl group, a cyano group, a nitro group, or an alkoxy group, and a positive integer n is greater than 2.

19. The method of claim 17, wherein inducing the crosslinking reaction comprises baking at a temperature less than 130° C. for fewer than 6 min.

20. The method of claim 17, wherein diffusing the portion of the plurality of acid particles comprises baking at a temperature less than 130° C. for fewer than 6 min.
